(19) United States
(12) Patent Application Publication
(10) Pub. No.: US 2025/0040412 A1
(43) Pub. Date: Jan. 30, 2025

(54) Display Panel and Near-Eye Display Apparatus

(71) Applicant: BOE Technology Group Co., Ltd., Beijing (CN)

(72) Inventors: Weiting PENG, Beijing (CN); Wei WANG, Beijing (CN); Qiuyu LING, Beijing (CN); Xianqin MENG, Beijing (CN); Pengxia LIANG, Beijing (CN); Xiaochuan CHEN, Beijing (CN)

(21) Appl. No.: 18/274,475

(22) PCT Filed: Jul. 28, 2022
(86) PCT No.: PCT/CN2022/108672

§ 371 Date: Jul. 27, 2023

(51) Int. Cl. H10K 59/80; G06F 3/01; G06T 19/00

(52) U.S. Cl. CPC H10K 59/879; G06F 3/011; G06T 19/003; H10K 59/873

(57) ABSTRACT

Disclosed are a display panel and a near-eye display apparatus. The display panel includes a central display region and an angle-customized display region surrounding the central display region, wherein the central display region and the angle-customized display region each includes a plurality of sub-pixels, a sub-pixel includes a light emitting device and a metasurface device corresponding to the light emitting device, a metasurface device in the angle-customized display region is configured such that light emitted by a corresponding light emitting device is deflected at a customized angle corresponding to the angle-customized display region.

### CROSS-REFERENCE TO RELATED APPLICATION

The present application is a U.S. National Phase Entry of International Application No. PCT/CN2022/108672 having an international filing date of Jul. 28, 2022. The entire contents of the above-identified application are hereby incorporated by reference.

### TECHNICAL FIELD

Embodiments of the present disclosure relate to, but are not limited to, the field of display technologies, and particularly to a display panel and a near-eye display apparatus.

### BACKGROUND

A silicon-based Organic Light Emitting Diode (OLED) combined with a Complementary Metal Oxide Semiconductor (CMOS) integrated circuit process and an OLED technology, has advantages of a small size, a high Pixel Per Inch (PPI), and a high refresh rate, and may be widely used in near-eye display fields, such as Virtual Reality (VR) or Augmented Reality (AR). However, since an OLED has characteristics of Lambert-type light emission, there are problems of low energy utilization and insufficient brightness when applied to an AR/VR display solution.

### SUMMARY

The following is a summary of subject matters described herein in detail. The summary is not intended to limit the protection scope of claims.

In a first aspect, an exemplary embodiment of the present disclosure provides a display panel including: a central display region and an angle-customized display region surrounding the central display region, wherein the central display region and the angle-customized display region each includes a plurality of sub-pixels, a sub-pixel includes a light emitting device and a metasurface device corresponding to the light emitting device; a metasurface device in the angle-customized display region is configured such that light emitted by a corresponding light emitting device is deflected at a customized angle corresponding to the angle-customized display region.

In an exemplary embodiment, the metasurface device includes a plurality of metasurface units arranged regularly, at least one of the plurality of metasurface units includes a base substrate and a post body disposed on the base substrate, and a refractive index of the base substrate is different from a refractive index of the post body.

In an exemplary embodiment, in the central display region, a pixel opening region of the sub-pixel has a first centerline extending along a first direction or a second centerline extending along a second direction, a plurality of metasurface units of the metasurface device are symmetrically disposed with respect to at least one of a geometric center of the sub-pixel, the first centerline, and the second centerline, the second direction intersects with the first direction, and an intersection point of the first centerline and the second centerline is the geometric center of the sub-pixel.

In an exemplary embodiment, pixel opening regions of the sub-pixels in the central display region and the angle-customized display region each include a first region, the first region includes a plurality of sub-regions, a diameter of a metasurface unit in a sub-region farther from a geometric center of the sub-pixel in the plurality of sub-regions is smaller, or a diameter of a metasurface unit in a sub-region farther from a geometric center of the first region in the plurality of sub-regions is smaller.

In an exemplary embodiment, the pixel opening regions of the sub-pixels in the central display region and the angle-customized display region further each include a second region that at least partially surrounds the first region, and a diameter of a metasurface unit in a region close to the first region in the second region is greater than a diameter of a metasurface unit in a region close to the second region in the first region.

In an exemplary embodiment, a diameter of a metasurface unit in a region farther from a geometric center of a sub-pixel in the second region of pixel opening regions of sub-pixels in the central display region is smaller.

In an exemplary embodiment, along a direction away from a geometric center of a display panel, the display panel includes N angle-customized display regions, a pixel opening region of a sub-pixel of at least one of the N angle-customized display regions further includes a third region located on a side of the first region away from the second region, wherein a diameter of a metasurface unit in a region close to the first region in the third region is smaller than a diameter of a metasurface unit in a region close to the third region in the first region, the diameter of the metasurface unit in the region close to the first region in the third region is smaller than a diameter of a metasurface unit in a region close to the first region in the second region, and N is a positive integer greater than 1.

In an exemplary embodiment, a distance between a geometric center of a sub-region where a metasurface unit with a largest diameter is located in the plurality of sub-regions in the angle-customized display region and the geometric center of the sub-pixel is a non-zero distance.

In an exemplary embodiment, the non-zero distance is greater than a pitch between two adjacent metasurface units.

In an exemplary embodiment, a distance between a geometric center of a sub-region where a metasurface unit with a largest diameter is located in the plurality of sub-regions in the central display region is located and the geometric center of the sub-pixel is a first distance, and a distance between a geometric center of a sub-region where a metasurface unit with a largest diameter is located in the plurality of sub-regions in the angle-customized display region and the geometric center of the sub-pixel is a second distance, and the first distance is less than the second distance.

In an exemplary embodiment, in the plurality of sub-regions in the central display region, a geometric center of a sub-region where a metasurface unit with a largest diameter is located coincides with the geometric center of the sub-pixel.

In an exemplary embodiment, along a direction away from a geometric center of the display panel, the display panel includes N angle-customized display regions, wherein a distance between a geometric center of a sub-region where a metasurface unit with a largest diameter is located in the plurality of sub-regions in an N-th angle-customized display region and the geometric center of the sub-pixel is a third distance, a distance between a geometric center of a sub-region where a metasurface unit with a largest diameter is located in the plurality of sub-regions in an (N−1)-th angle-customized display region and the geometric center of the sub-pixel is a fourth distance, the third distance is greater than the fourth distance, and N is a positive integer greater than 1.

In an exemplary embodiment, the first region has a first reference line extending along a first direction or a second reference line extending along a second direction, and in the plurality of sub-regions in the angle-customized display region, metasurface units in at least one of the sub-regions are symmetrically disposed with respect to one of the first reference line and the second reference line.

In an exemplary embodiment, along a direction away from a geometric center of the display panel, the display panel includes N angle-customized display regions, wherein a customized angle corresponding to an N-th angle-customized display region is greater than a customized angle corresponding to an (N−1)-th angle-customized display region, and N is a positive integer greater than 1.

In an exemplary embodiment, the metasurface device in the angle-customized display region satisfies a following phase equation.

$$φ ( x , y ) = - 2 π n ( \sqrt{( {x}^{2} + {y}^{2} ) + {f}^{2}} - f ) / λ + 2 π n ( x cos ϕ + y sin ϕ ) sin θ / λ$$

Herein (x, y) represents coordinates of different position points on the metasurface device, the geometric center of the metasurface device is an origin of the coordinates, φ(x, y) represents a phase at a position point (x, y) on the metasurface device, λ represents a wavelength of incident light, f represents a focal length of a lens when the metasurface device expresses a phase of a beam collection lens, ϕ represents a grating angle when the metasurface device expresses a phase of a deflection grating, and θ is the customized angle corresponding to the angle-customized display region.

In an exemplary embodiment, the metasurface device in the angle-customized display region is further configured to enable deflected light to be incident to a lens located on a light exit side of the display panel, and the customized angle corresponding to the angle-customized display region satisfies following equations.

$${θ}_{X} = {tan}^{- 1} \frac{{L}_{1 X} ( 1 - {L}_{2} / {L}_{1} )}{{d}_{1}}$$

$${θ}_{Y} = {tan}^{- 1} \frac{{L}_{1 Y} ( 1 - {L}_{2} / {L}_{1} )}{{d}_{1}}$$

Herein θ_{X} represents a deflection angle of light in an x direction, θ_{Y} represents a deflection angle of light in a y direction, (L_{1X}, L_{1Y}) represents coordinates of a sub-pixel in the angle-customized display region, L₁ represents a length of a display region of the display panel, L₂ represents the diameter of the lens, d₁ represents a distance between the lens and the display panel.

In an exemplary embodiment, along a direction away from a geometric center of the display panel, the display panel includes: two angle-customized display regions; the metasurface device in the angle-customized display region is further configured to enable deflected light to be incident to a lens located on a light exit side of the display panel; a customized angle corresponding to an angle-customized display region farther from the center of the display panel satisfies a following equation:

$${θ}_{1} = {tan}^{- 1} \frac{( {L}_{1} - {L}_{2} ) / 2}{{d}_{1}} ;$$

a customized angle corresponding to an angle-customized display closer to the center of the display panel satisfies a following equation:

$${θ}_{2} = {tan}^{- 1} \frac{( {L}_{1} - {L}_{2} ) / 4}{{d}_{1}} ;$$

wherein L₁ represents a length of a display region of the display panel, L₂ represents a diameter of the lens, d₁ represents a distance between the lens and the display panel.

In an exemplary embodiment, a ratio of a length of the central display region to a length of the display region of the display panel is 0.5, a ratio of a length of the angle-customized display region close to the center of the display panel to the length of the display region of the display panel is 0.75, and a ratio of the length of the angle-customized display region away from the center of the display panel to the length of the display region of the display panel is 1.

In an exemplary embodiment, the post body is a cylinder, and in at least one metasurface device, a radius of the cylinder is 50 nm to 90 nm; or, the radius of the cylinder is 55 nm to 110 nm; or, the radius of the cylinder is 55 nm to 140 nm.

In an exemplary embodiment, in a direction perpendicular to a plane of the display panel, the display panel includes a base substrate, a light emitting structure layer located on a side of the base substrate, and a metasurface structure layer disposed on a side of the light emitting structure layer away from the base substrate, the light emitting structure layer includes a plurality of light emitting devices, and the metasurface structure layer includes a plurality of metasurface devices.

In an exemplary embodiment, the display panel further includes an encapsulation layer and a cover plate layer, the encapsulation layer is disposed on a side of the metasurface structure layer close to the light emitting structure layer, and the cover plate layer is disposed on a side of the metasurface structure layer away from the light emitting structure layer.

In a second aspect, an exemplary embodiment of the present disclosure also provides a near-eye display apparatus, including the display panel in the above embodiment and a light modulation device located on a light exit side of the display panel. A metasurface device in an angle-customized display region of the display panel is configured such that light emitted by a corresponding light emitting device is deflected at a customized angle corresponding to the angle-customized display region and incident to the light modulation device.

In an exemplary embodiment, the light modulation device includes a lens.

Other features and advantages of the present disclosure will be set forth in following specification, and moreover, partially become apparent from the specification or are understood by implementing the present disclosure. Other advantages of the present disclosure may be achieved and obtained through solutions described in the specification and drawings.

Other aspects may become clear after the drawings and the detailed description are read and understood.

### BRIEF DESCRIPTION OF DRAWINGS

The drawings are used for providing understanding of technical solutions of the present disclosure, constitute a part of the specification, and together with the embodiments of the present disclosure, are used for explaining the technical solutions of the present disclosure but do not constitute limitations on the technical solutions of the present disclosure. A shape and a size of each component in the drawings do not reflect an actual scale, and are only intended to schematically illustrate contents of the present disclosure.

FIG. 1 is a schematic diagram of a structure of a silicon-based OLED display panel.

FIG. 2 is a schematic diagram of a planar structure of a silicon-based OLED display panel.

FIG. 3 is a schematic diagram of a structure of a display panel according to an exemplary embodiment of the present disclosure.

FIG. 4A is a schematic diagram of a structure of the display panel shown in FIG. 3.

FIG. 4B is a schematic diagram of another structure of the display panel shown in FIG. 3.

FIG. 5 is a schematic diagram of a distribution of angle-customized display regions according to an exemplary embodiment of the present disclosure.

FIG. 6 is a schematic diagram of an application scenario according to an exemplary embodiment of the present disclosure.

FIG. 7 is a schematic diagram of an angular spectrum of light emission angle adjustment and control according to an exemplary embodiment of the present disclosure.

FIG. 8 is a schematic diagram of a structure of a metasurface unit according to an exemplary embodiment of the present disclosure.

FIG. 9 is a schematic diagram of a structure of a metasurface device according to an exemplary embodiment of the present disclosure.

FIG. 10 is a schematic diagram of a structure of a metasurface device of a central display region according to an exemplary embodiment of the present disclosure.

FIG. 11 is a schematic diagram of a structure of a metasurface device of a first angle-customized display region according to an exemplary embodiment of the present disclosure.

FIG. 12 is a schematic diagram of a structure of a metasurface device of a second angle-customized display region according to an exemplary embodiment of the present disclosure.

FIG. 13 is a schematic diagram of the metasurface unit in FIGS. 10 to 12.

FIG. 14 is a schematic diagram of parameters of a metasurface unit structure library according to an exemplary embodiment of the present disclosure.

FIG. 15 is a schematic diagram of parameters of an application scenario according to an exemplary embodiment of the present disclosure.

FIG. 16 is a schematic diagram of design parameters of a display panel according to an exemplary embodiment of the present disclosure.

FIG. 17 is a schematic diagram of angular spectrum changes of a light emitting device in a display panel before and after light emitting angle adjustment and control according to an exemplary embodiment of the present disclosure.

FIG. 18 is a schematic diagram of a structure of a near-eye display apparatus according to an exemplary embodiment of the present disclosure.

### DETAILED DESCRIPTION

The embodiments of the present disclosure will be described in detail below with reference to the drawings. It is to be noted that implementation modes may be implemented in a plurality of different forms. Those of ordinary skills in the art may easily understand such a fact that modes and contents may be transformed into various forms without departing from the purpose and scope of the present disclosure. Therefore, the present disclosure should not be explained as being limited to contents described in following implementation modes only. The embodiments in the present disclosure and features in the embodiments may be combined randomly with each other without conflict. In order to keep following description of the embodiments of the present disclosure clear and concise, detailed description of a portion of known functions and known components is omitted in the present disclosure. The drawings of the embodiments of the present disclosure only involve structures involved in the embodiments of the present disclosure, and other structures may refer to usual designs.

A scale of the drawings in the present disclosure may be used as a reference in an actual process, but is not limited thereto. For example, a width-length ratio of a channel, a thickness and a pitch of each film layer, and the like may be adjusted according to actual needs. For example, in the drawings, a size of each constituent element, a thickness of a layer, or a region is exaggerated sometimes for clarity. Therefore, a mode of the present disclosure is not necessarily limited to the size, and a shape and size of each component in the drawings do not reflect a true proportion. In addition, the drawings schematically illustrate ideal examples, and one mode of the present disclosure is not limited to shapes, numerical values, or the like shown in the drawings.

The “first”, “second”, “third” and other ordinal numbers in exemplary embodiments of the present disclosure are set to avoid confusion of constituent elements, not to limit a quantity.

In the exemplary embodiments of the present disclosure, for the sake of convenience, wordings such as “central”, “upper”, “lower”, “front”, “rear”, “vertical”, “horizontal”, “top”, “bottom”, “inner”, “outer”, and the like describing orientations or positional relationships are used for depicting positional relationship of constituent elements with reference to the drawings, and are only for convenience of describing the specification and simplifying the description, rather than for indicating or implying that an apparatus or element referred to must have a specific orientation, or must be constructed and operated in a particular orientation, and therefore, those wordings cannot be construed as limitations on the present disclosure. The positional relationships between the constituent elements may be changed as appropriate according to a direction of describing each constituent element. Therefore, appropriate replacements may be made according to situations without being limited to the wordings described in the specification.

In the exemplary embodiments of the present disclosure, terms “installation”, “mutual connection”, and “connection” shall be broadly understood unless otherwise explicitly specified and defined. For example, it may be a fixed connection, or a detachable connection, or an integrated connection. It may be a mechanical connection or an electrical connection. It may be a direct mutual connection, or an indirect connection through middleware, or internal communication between two elements. Those of ordinary skills in the art may understand meanings of the above-mentioned terms in the present disclosure according to situations.

In the exemplary embodiments of the present disclosure, an “electrical connection” includes a case where constituent elements are connected via an element with a certain electrical effect. The “element with a certain electrical effect” is not particularly limited as long as electrical signals may be sent and received between the connected constituent elements. For example, the “element with a certain electrical effect” may be an electrode or wiring, or a switching element such as a transistor, or another functional element, such as a resistor, an inductor, and a capacitor.

In the exemplary embodiments of the present disclosure, a transistor refers to an element that at least includes three terminals, i.e., a gate electrode (a gate or a control electrode), a drain electrode (a drain electrode terminal, a drain region, or a drain), and a source electrode (a source electrode terminal, a source region, or a source). The transistor has a channel region between the drain electrode and the source electrode, and a current can flow through the drain electrode, the channel region, and the source electrode. It is to be noted that, in the specification, the channel region refers to a region through which the current mainly flows.

In the exemplary embodiments of the present disclosure, in order to distinguish two electrodes of a transistor other than a gate electrode (a gate or a control electrode), one of the two electrodes is directly described as a first electrode, while the other is described as a second electrode. Among them, the first electrode may be a drain electrode and the second electrode may be a source electrode. Or, the first electrode may be a source electrode and the second electrode may be a drain electrode. In a case that transistors with opposite polarities are used, in a case that a direction of a current is changed during operation of a circuit, or the like, functions of the “source electrode” and the “drain electrode” are sometimes interchangeable. Therefore, the “source electrode” and the “drain electrode” are interchangeable in the specification.

In the exemplary embodiments of the present disclosure, “parallel” refers to a state in which an angle formed by two straight lines is more than −10° and less than 10°, and thus also includes a state in which the angle is more than −5° and less than 5°. In addition, “perpendicular” refers to a state in which an angle formed by two straight lines is more than 80° and less than 100°, and thus also includes a state in which the angle is more than 85° and less than 95°.

In the specification, a “film” and a “layer” are interchangeable. For example, a “conductive layer” may be replaced with a “conductive film” sometimes. Similarly, an “insulation film” may be replaced with an “insulation layer” sometimes.

A triangle, a rectangle, a trapezoid, a pentagon, or a hexagon, etc. in this specification is not strictly defined, and it may be an approximate triangle, an approximate rectangle, an approximate trapezoid, an approximate pentagon, or an approximate hexagon, etc. There may be some small deformation caused by tolerance, and there may be a chamfer, an arc edge, and deformation, etc.

In the exemplary embodiments of the present disclosure, “about” means that a boundary is not strictly limited, and values within an error range of processes and measurement are allowed.

In the exemplary embodiments of the present disclosure, a first direction DR1 may refer to an extension direction of a data signal line in a display region or a horizontal direction, a second direction DR2 may refer to an extension direction of a scan signal line in the display region or a vertical direction, and a third direction DR3 may refer to a direction perpendicular to a plane of a display panel or a thickness direction of a display panel, etc. Herein, the first direction DR1 intersects with the second direction DR2, and the first direction DR1 intersects with the third direction DR3. For example, the first direction DR1 and the second direction DR2 may be perpendicular to each other, and the first direction DR1 and the third direction DR3 may be perpendicular to each other.

Virtual Reality (VR) and Augmented Reality (AR) apparatuses have been gradually applied to display, games, medical care, and other fields. A near-eye display technology for achieving VR/AR has attracted more and more attention and research. Near-eye display is a display technology that enables a viewer to be able to see contents very close to an eye clearly. An optical system is used for image displayed contents within a focus range of the eye, so that the eye can see the displayed contents clearly.

A light emitting energy distribution of an OLED is of a Lambert type, so in a positive viewing angle direction (within a range of ±15°) of a display device, an energy utilization rate is usually only about 40% and positive viewing angle brightness is low. Moreover, due to a large light emitting angle (±80°) of a single pixel, an overall field angle of the device is large. However, in VR/AR display, visual angles of pixels at different positions of a screen are different to human eyes, and a visual angle of each pixel is very narrow. Therefore, there is a large energy loss for VR/AR and other scenes that are only applied to a small field of view of pixels.

In some technologies, solutions of angle adjustment for an OLED mainly include: a solution based on microlens array and a solution based on grating deflection. However, the solution based on microlens array will have a problem of large-angle color deviation of lens, while the solution based on grating deflection requires collimation of a light source. On Lambert-type OLED devices, there is usually a problem of low efficiency and high noise caused by insufficient collimation of a light source.

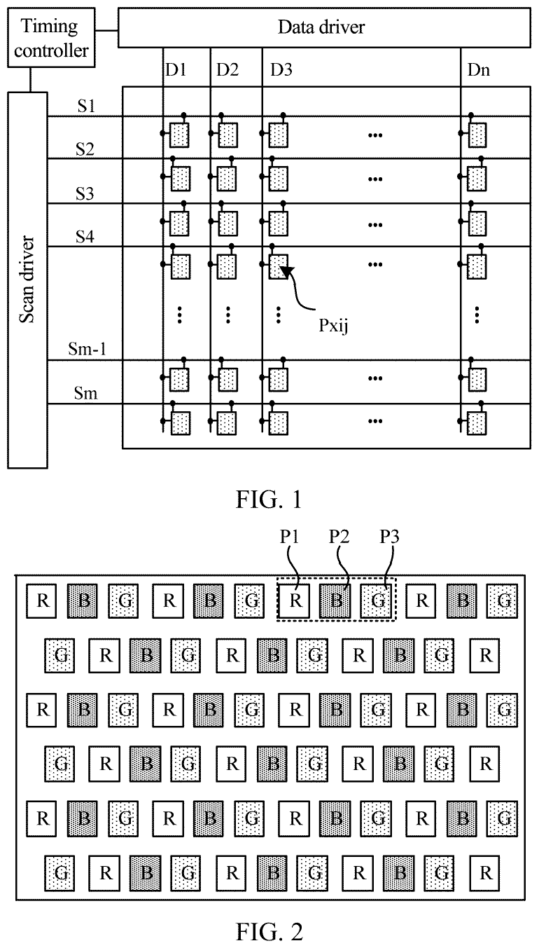

FIG. 1 is a schematic diagram of a structure of a silicon-based OLED display panel. As shown in FIG. 1, a silicon-based OLED display apparatus may include a timing controller, a data signal driver, a scan signal driver, and a pixel array. The pixel array may include multiple scan signal lines (S1 to Sm), multiple data signal lines (D1 to Dn), and multiple sub-pixels Pxij. For example, the timing controller may provide a grayscale value and a control signal that are suitable for a specification of the data signal driver to the data signal driver, and may provide a clock signal, a scan start signal, and the like that are suitable for a specification of the scan signal driver to the scan signal driver. The data signal driver may generate a data voltage to be provided to the data signal lines D1, D2, D3, . . . , and Dn using the grayscale value and the control signal that are received from the timing controller. For example, the data signal driver may sample the grayscale value using the clock signal and apply a data voltage corresponding to the grayscale value to the data signal lines D1 to Dn by taking a sub-pixel row as a unit, wherein n may be a natural number. For example, the scan signal driver may generate a scan signal to be provided to the scan signal lines S1, S2, S3, . . . , and Sm by receiving the clock signal, the scan start signal, and the like from the timing controller. For example, the scan signal driver may sequentially provide a scan signal with an on-level pulse to the scan signal lines S1 to Sm. For example, the scan signal driver may be constructed in a form of a shift register and may generate a scan signal in a manner of sequentially transmitting a scan start signal provided in a form of an on-level pulse to a next-stage circuit under control of the clock signal, wherein m may be a natural number. For example, each sub-pixel Pxij may be connected to a corresponding data signal line and a corresponding scan signal line, wherein i and j may be natural numbers. The sub-pixel Pxij may refer to a sub-pixel in which a transistor is connected to an i-th scan signal line and is connected to a j-th data signal line.

FIG. 2 is a schematic diagram of a planar structure of a silicon-based OLED display panel. As shown in FIG. 2, the display panel may include a plurality of pixel units arranged in a matrix. At least one of the plurality of pixel units may include a first sub-pixel P1 emitting light of a first color, a second sub-pixel P2 emitting light of a second color, and a third sub-pixel P3 emitting light of a third color. For example, the first sub-pixel P1 may be a red sub-pixel emitting Red (R) light, the second sub-pixel P2 may be a blue sub-pixel emitting Blue (B) light, and the third sub-pixel P3 may be a green sub-pixel emitting Green (G) light. For example, each of the three sub-pixels may include a light emitting device and a pixel drive circuit, wherein a pixel drive circuit in a sub-pixel is respectively connected with a scan signal line and a data signal line, and the pixel drive circuit is configured to receive a data voltage transmitted by the data signal line under control of the scan signal line and output a corresponding current to the display light emitting device. A light emitting device in the sub-pixel is respectively connected with the pixel drive circuit of the sub-pixel where the light emitting device is located, and the light emitting device is configured to emit light with corresponding brightness in response to the current output by the pixel drive circuit of the sub-pixel where the light emitting device is located. For example, a pixel unit may include four sub-pixels. Here, no limitation is made thereto in embodiments of the present disclosure.

In an exemplary embodiment, the plurality of sub-pixels may include any one or more of a first sub-pixel P1 that emits light of a first color, a second sub-pixel P2 that emits light of a second color, a third sub-pixel P3 that emits light of a third color, and a fourth sub-pixel P4 that emits light of a fourth color. For example, the first sub-pixel P1 may be a red sub-pixel emitting Red (R) light, the second sub-pixel P2 may be a blue sub-pixel emitting Blue (B) light, and the third sub-pixel P3 may be a green sub-pixel emitting Green (G) light, the fourth sub-pixel P4 may be a white sub-pixel emitting White (W) light. Here, no limitation is made thereto in embodiments of the present disclosure.

In an exemplary embodiment, a shape of a sub-pixel may be any one or more of a triangle, a square, a rectangle, a rhombus, a trapezoid, a parallelogram, a pentagon, a hexagon, and another polygon, and may be arranged in parallel in a horizontal direction, in parallel in a vertical direction, in a shape of a square, or in a diamond shape, etc., which is not limited in the present disclosure.

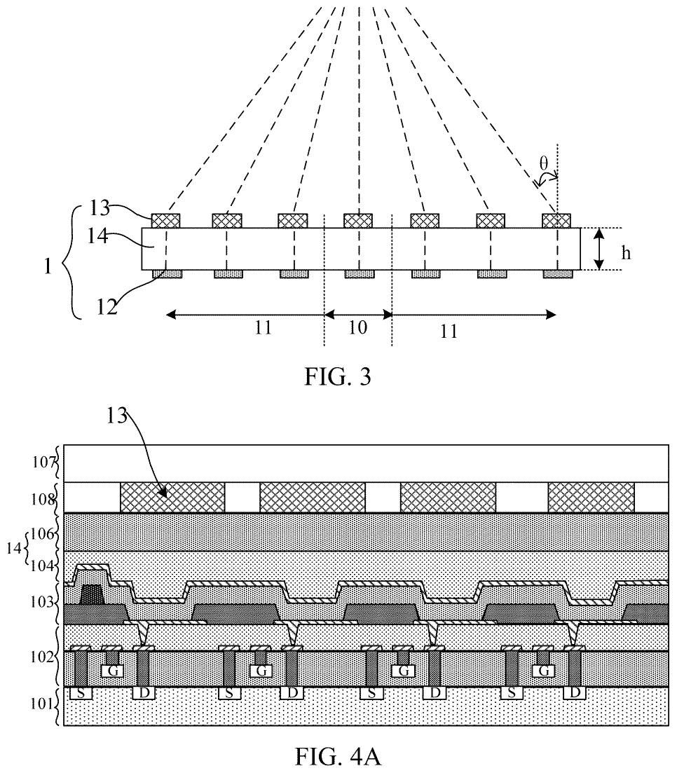

An exemplary embodiment of the present disclosure provides a display panel. FIG. 3 is a schematic diagram of a structure of the display panel according to the exemplary embodiment of the present disclosure. As shown in FIG. 3, a display panel 1 may include a central display region 10 and an angle-customized display region 11, wherein the angle-customized display region 11 may be located on at least one side of the central display region 10, for example, the angle-customized display region 11 may at least partially surround the central display region 10. For example, the central display region 10 may be located at a middle position of the display region of the display panel and the angle-customized display region 11 may peripherally surround the central display region 10. The central display region 10 and the angle-customized display region 11 may each include a plurality of sub-pixels, and at least one sub-pixel of the plurality of sub-pixels may include a light emitting device 12 and a metasurface device 13 corresponding to the light emitting device 12. The metasurface device 13 in the angle-customized display region 11 is configured such that light emitted by a corresponding light emitting device 12 is deflected at a customized angle θ corresponding to the angle-customized display region 11.

For example, the metasurface device 13 in the central display region 10 may be configured not to deflect light such that light emitted by the light emitting device corresponding to the metasurface device 13 in the central display region 10 may be directly emitted, i.e., a deflection angle corresponding to the central display region 10 may be 0°.

In an exemplary embodiment, a metasurface device may be formed by arranging metasurface units whose dimensions are smaller than a wavelength of incident light according to a certain arrangement rule, and the metasurface units can accurately modulate a phase of incident light with their micro-nano structure optical modulation characteristics, thereby achieving a light emitting shaping function, a beam collection function, and a light deflection function. As a new type of optical control element, the metasurface device may achieve phase modulation of light through a sub-wavelength unit structure. A whole device may perform required phase expression of a light adjustment and control device through a large number of unit structures, so as to output whole device performance. Due to a high design freedom degree and its own advantages in scale (a structural thickness in an order of 100 nanometers) of a metasurface unit, the metasurface unit can break through processing difficulties of traditional optical components, be not limited by a traditional geometrical optics theory, and meet requirements of arbitrary light field adjustment and control, and an ultra-thin, flat, and aberration-free optical device may be manufactured by using a simple process on a smaller scale. The metasurface unit has characteristics of strong design nature, a small structural size, a high integration level, and an accurate light control design.

In an exemplary embodiment, the metasurface device achieves pixel light emitting adjustment and control through expression of a desired light field adjustment and control phase surface through the metasurface units, so that light has a desired adjustment and control effect after passing through the metasurface device.

In an exemplary embodiment, the light emitting device may include, but is not limited to, a light emitting device having a Lambert-type light emitting energy distribution, such as an OLED, a Quantum dot Light Emitting Diode (QLED), a light emitting diode (Micro LED or Mini LED), or a Quantum Dot Light Emitting Diode (QDLED). Here, no limitation is made thereto in embodiments of the present disclosure.

Thus, in the display panel according to the exemplary embodiment of the present disclosure, a light emitting angle of light emitted by the light emitting device is deflected and adjusted at a customized angle through the metasurface device in the angle-customized display region, so that light emitting energy concentration of the light emitting device may be achieved, thereby, an energy utilization rate of the light emitting device may be improved, and a customization requirement of a light emitting angle of a sub-pixel may be achieved. Moreover, by constructing a metasurface device with light modulation characteristics in a sub-pixel, performance of the light emitting device may be improved, at the same, it is beneficial to ensured thinness and lightness of the display panel. In this way, a high-performance display panel with high brightness, thinness, and a designable viewing field angle may be achieved. Furthermore, when the display panel is applied to a display solution with high requirements on display brightness and resolution, such as AR/VR, an energy utilization rate of the light emitting device within an applicable viewing field angle range may be increased, and brightness enhancement within a viewing angle range may be achieved.

In an exemplary embodiment, as shown in FIG. 3, the display panel 1 may further include an encapsulation layer 14 disposed between the light emitting device 12 and the metasurface device 13.

In an exemplary embodiment, the encapsulation layer 14 has a certain thickness H and is configured to ensure a flat light emitting device 12 and a placement height of the metasurface device 13 to obtain optimum beam collection and deflection effects.

In an exemplary embodiment, the encapsulation layer 14 may be any one or more of Silicon Oxide (SiOx), Silicon Nitride (SiNx), and Silicon Oxidenitride (SiON), the encapsulation layer 14 may be a single layer, a multi-layer, or a composite layer, a manner of Thin Film Encapsulation (TFE), a manner of Chemical Vapor Deposition (CVD) or Atomic Layer Deposition (ALD), etc. may be adopted. Thus, on one hand, the flat light emitting device 12 and the placement height of the metasurface device 13 may be ensured, and on the other hand, it may be ensured that external water and oxygen cannot enter a film layer where the light emitting device 12 is located.

In an exemplary embodiment, a pixel opening region of a sub-pixel in the central display region has a first centerline extending along a first direction or a second centerline extending along a second direction, a plurality of metasurface units of the metasurface device may be symmetrically disposed with respect to at least one of a geometric center of a corresponding sub-pixel, the first centerline, and the second centerline, wherein the second direction DR2 intersects with the first direction DR1, and an intersection point of the first centerline and the second centerline may be the geometric center of the sub-pixel. For example, the geometric center of the sub-pixel may refer to a geometric center of the pixel opening region of the sub-pixel.

In an exemplary embodiment, a pixel opening region of a sub-pixel in the central display region and the angle-customized display region may each include a first region, and the first region may include a plurality of sub-regions, and a diameter of a metasurface unit in a sub-region in the plurality of sub-regions farther from the geometric center of the sub-pixel is smaller.

In an exemplary embodiment, the pixel opening region of the sub-pixel in the central display region and the angle-customized display region may further include a second region that at least partially surrounds the first region, and a diameter of a metasurface unit in a region close to the first region in the second region is greater than a diameter of a metasurface unit in a region close to the second region in the first region.

In an exemplary embodiment, a diameter of a metasurface unit in a region farther from the geometric center of the sub-pixel in the second region of the pixel opening region of the sub-pixel in the central display region is smaller.

In an exemplary embodiment, along a direction away from a geometric center of a display panel, the display panel includes N angle-customized display regions, a pixel opening region of a sub-pixel of at least one of the N angle-customized display regions further includes a third region located on a side of the first region away from the second region, wherein a diameter of a metasurface unit in a region close to the first region in the third region is smaller than a diameter of a metasurface unit in a region close to the third region in the first region, the diameter of the metasurface unit in the region close to the first region in the third region is smaller than a diameter of a metasurface unit in a region close to the first region in the second region, and N is a positive integer greater than 1.

In an exemplary embodiment, a distance between a geometric center of a sub-region where a metasurface unit with a largest diameter is located in the plurality of sub-regions in the angle-customized display region and a geometric center of a sub-pixel is a non-zero distance. For example, the non-zero distance is greater than a pitch between two adjacent metasurface units. Among them, the pitch between the two adjacent metasurface units may refer to a distance between geometric centers of the two adjacent metasurface units.

In an exemplary embodiment, a distance between a geometric center of a sub-region where a metasurface unit with a largest diameter in the plurality of sub-regions in the central display region is located and the geometric center of the sub-pixel may be a first distance, and a distance between a geometric center of a sub-region where a metasurface unit with a largest diameter is located in the plurality of sub-regions in the angle-customized display region and the geometric center of the sub-pixel may be a second distance, the first distance is less than the second distance. For example, the geometric center of the sub-region where the metasurface unit with the largest diameter is located in the plurality of sub-regions in the central display region may coincide with the geometric center of the sub-pixel, and the geometric center of the sub-region where the metasurface unit with the largest diameter is located in the plurality of sub-regions in the angle-customized display region may not coincide with the geometric center of the sub-pixel.

In an exemplary embodiment, along a direction away from a geometric center of the display panel, the display panel includes N angle-customized display regions, wherein a distance between a geometric center of a sub-region where a metasurface unit with a largest diameter is located in a plurality of sub-regions in a pixel opening region of a sub-pixel in an N-th angle-customized display region and a geometric center of the sub-pixel is a third distance, a distance between a geometric center of a sub-region where a metasurface unit with a largest diameter is located in a plurality of sub-regions in a pixel opening region in a sub-pixel in an (N−1)-th angle-customized display region and a geometric center of the sub-pixel is a fourth distance, the third distance is greater than the fourth distance, and N is a positive integer greater than 1.

In an exemplary embodiment, the first region in the pixel opening region of the sub-pixel of the angle-customized display region may have a first reference line extending along the first direction or a second reference line extending along the second direction, and in a plurality of sub-regions in the pixel opening region of the sub-pixel of the angle-customized display region, a metasurface unit in at least one of the sub-regions may be symmetrically disposed with respect to one of the first reference line and the second reference line, wherein the second direction DR2 intersects with the first direction DR1.

In an exemplary embodiment, along a direction away from a geometric center of the display panel, the display panel includes N angle-customized display regions, wherein a customized angle corresponding to an N-th angle-customized display region may be greater than a customized angle corresponding to an (N−1)-th angle-customized display region, and N is a positive integer greater than 1.

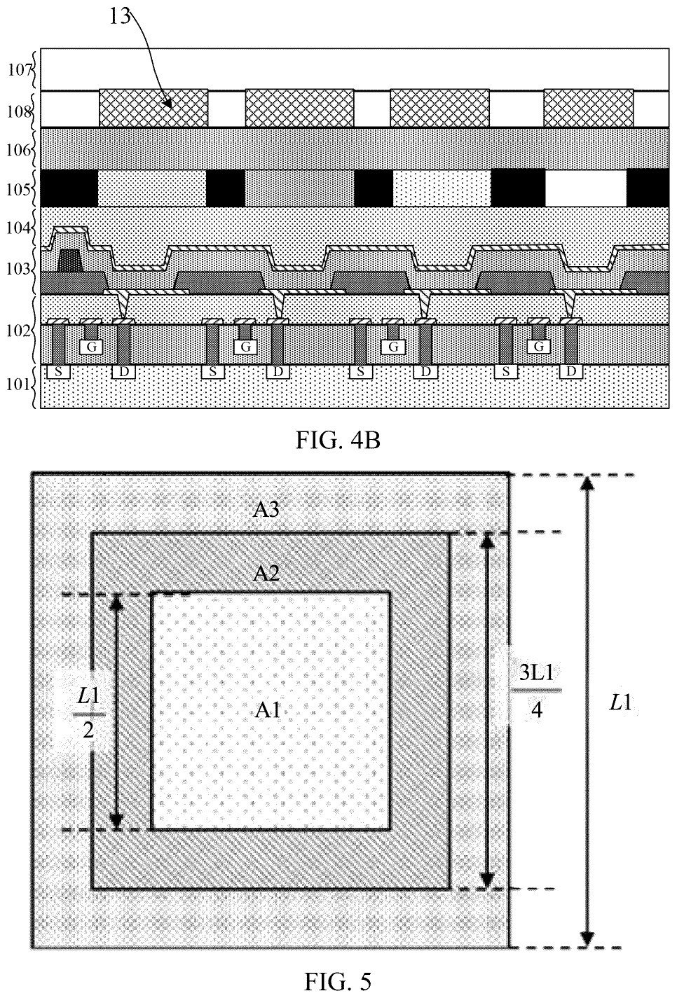

FIG. 4A is a schematic diagram of a structure of the display panel shown in FIG. 3, and FIG. 4B is a schematic diagram of another structure of the display panel shown in FIG. 3. In FIG. 4A, illustration is performed by taking a case that a structure for achieving monochrome display is adopted for the display panel as an example, and in FIG. 4B, illustration is performed by taking a case that a structure in which a manner of white light+color film is adopted for the display panel to achieve color display as an example.

In an exemplary embodiment, taking a case that a light emitting color of a sub-pixel is monochromatic as an example, as shown in FIG. 4A, on a plane perpendicular to the display panel, the display panel may include a base substrate 101, a drive circuit layer 102 disposed on the base substrate 101, a light emitting structure layer 103 disposed on a side of the drive circuit layer 102 away from the base substrate 101, a first encapsulation layer 104 disposed on a side of the light emitting structure layer 103 away from the base substrate 101, a second encapsulation layer 106 disposed on a side of the first encapsulation layer 104 away from the base substrate 101, a metasurface structure layer 108 disposed on a side of the second encapsulation layer 106 away from the base substrate 101, and a cover plate layer 107 disposed on a side of the metasurface structure layer 108 away from the base substrate 101. Among them, in FIG. 4A, illustration is performed by taking a case that the encapsulation layer 14 is implemented by adopting a double-layer structure (including the first encapsulation layer 104 and the second encapsulation layer 106).

In an exemplary embodiment, taking a case that a light emitting color of a sub-pixel is colored as an example, as shown in FIG. 4B, on a plane perpendicular to the display panel, the display panel may include a base substrate 101, a drive circuit layer 102 disposed on the base substrate 101, a light emitting structure layer 103 disposed on a side of the drive circuit layer 102 away from the base substrate 101, a first encapsulation layer 104 disposed on a side of the light emitting structure layer 103 away from the base substrate 101, a color film structure layer 105 disposed on a side of the first encapsulation layer 104 away from the base substrate 101, a second encapsulation layer 106 disposed on a side of the color film structure layer 105 away from the base substrate 101, a metasurface structure layer 108 disposed on a side of the second encapsulation layer 106 away from the base substrate 101, and a cover plate layer 107 disposed on a side of the metasurface structure layer 108 away from the base substrate 101. Among them, in FIG. 4B, illustration is performed by taking a case that the encapsulation layer 14 is implemented by adopting a double-layer structure (including the first encapsulation layer 104 and the second encapsulation layer 106).

In an exemplary embodiment, the base substrate 101 may be a silicon substrate. For example, the silicon substrate may be a bulk silicon substrate or a Silicon-On-Insulator (SOI) substrate. For example, the drive circuit layer 102 may be prepared on the silicon base substrate 101 through a silicon semiconductor process (e.g., a CMOS process). For example, the drive circuit layer 102 may include a plurality of circuit units, a circuit unit may at least include a pixel drive circuit connected with a scan signal line and a data signal line, respectively, and the pixel drive circuit unit may include a plurality of transistors and a storage capacitor. A transistor may include a control electrode G, a first electrode S, and a second electrode D. The control electrode G, the first electrode S, and the second electrode D may be respectively connected with corresponding connection electrodes through vias filled with wolfram metal (i.e., wolfram vias, W-vias), and may be connected with other electrical structures (such as wires) through the connection electrodes.

In an exemplary embodiment, a manner of Thin Film Encapsulation (TFE) may be adopted for the first encapsulation layer 104 and the second encapsulation layer 106, which may ensure that external water vapor cannot enter the light emitting structure layer and may ensure a placement height of the metasurface structure layer.

In an exemplary embodiment, the light emitting structure layer 103 may include a plurality of light emitting devices 12, and a light emitting device 12 may at least include an anode, an organic emitting layer, and a cathode. For example, the anode may be connected with a second electrode D of a transistor through a connection electrode, the organic emitting layer is connected with the anode, the cathode is connected with the organic emitting layer, the cathode is connected with a second power supply line, and the organic emitting layer emits light under drive of the anode and the cathode.

In an exemplary embodiment, the organic emitting layer may include an Emitting Layer (EML), and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). For example, for sub-pixels emitting white light, organic emitting layers of all sub-pixels may be connected together to be a common layer.

In an exemplary embodiment, the anode may be made of a metal material or a transparent conductive material. The metal material may include any one or more of Argentum (Ag), Copper (Cu), Aluminum (Al), Titanium (TI), and Molybdenum (Mo), or an alloy material of the above metals. The transparent conductive material may include Indium Tin Oxide (ITO) or Indium Zinc Oxide (IZO). For example, the anode may be of a single-layer structure or a multi-layer composite structure, such as ITO/Al/ITO.

In an exemplary embodiment, the cathode may be made of any one or more of Magnesium (Mg), Argentum (Ag), Aluminum (Al), Copper (Cu), and Lithium (Li), or an alloy made of any one or more of the above metals.

In an exemplary embodiment, the cover plate layer 107 may be made of a glass material or a transparent material having flexible properties, such as plastic cement colorless polyimide.

In an exemplary embodiment, the color film structure layer 105 may include a Black Matrix (BM) and a plurality of Color Filters (CFs), the black matrix may be located between adjacent color filters. For example, a Color Filter (CF) may include a red filter, a green filter, and a blue filter that filter white light emitted from the light emitting device into Red (R) light, Green (G) light, and Blue (B) light. For example, the red filter, the green filter, and the blue filter are respectively and correspondingly disposed in the red sub-pixel, the green sub-pixel, and the blue sub-pixel.

In an exemplary embodiment, one light emitting device and a corresponded metasurface device, pixel drive circuit, and color filter may be divided into a sub-pixel, or one light emitting device and a corresponded metasurface device and pixel drive circuit may be divided into one sub-pixel.

In an exemplary embodiment, the display panel may include, but is not limited to, an OLED display panel, a QLED display panel, a Micro LED display panel, a Mini LED display panel, a QDLED display panel, or the like. Here, no limitation is made thereto in embodiments of the present disclosure.

In an exemplary embodiment, a display region AA of the display panel may be divided into regions, and a metasurface device having a beam collection function and a light deflection function is designed in a corresponding pixel region according to a deflection angle requirement of a corresponding region.

In an exemplary embodiment, a quantity of angle-customized display regions 11 in the display panel may be one or more, such as two, three, four, five, or six. Here, no limitation is made thereto in embodiments of the present disclosure.

For example, taking a case that along a direction away from a geometric center of a display panel, the display panel includes two angle-customized display regions around a central display region, as an example, as shown in FIG. 5, on a plane parallel to the display panel, a display region (AA) of the display panel may include a first display region A1, a second display region A2, and a third display region A3 disposed concentrically, the second display region A2 may surround the first display region A1, the third display region A3 may surround the second display region A2, wherein the first display region A1 may serve as a central display region 10 in the display panel, the second display region A2 may serve as an angle-customized display region 11 closer to the center of the display panel, and the third display region A3 may serve as an angle-customized display region 11 farther from the center of the display panel.

In an exemplary embodiment, a light deflection angle required for a sub-pixel in the third display region A3 is greater than a light deflection angle required for a sub-pixel in the second display region A2, and the light deflection angle required for the sub-pixel in the second display region A2 is greater than a light deflection angle required for a sub-pixel in the first display region A1. For example, each sub-pixel in the first display region A1 does not need a deflection angle, that is, a customized angle corresponding to the first display region A1 is 0°, and a customized angle corresponding to the second display region A2 may be designed as a second deflection angle θ₂, a customized angle corresponding to the third display region A3 may be designed as a first deflection angle θ₁, and the second deflection angle θ₂ is less than the first deflection angle θ₁.

In an exemplary embodiment, taking a case that the display panel is applied to a display solution that has higher requirements on display brightness and resolution, such as AR/VR, as an example, a lens may be disposed on a light exit side of the display panel, then the metasurface device in the angle-customized display region 11 may also be configured such that deflected light is incident to the lens located on the light exit side of the display panel.

In an exemplary embodiment, as shown in FIG. 5, a ratio of a length of a central display region (i.e., the first display region A1) to a length of the display region of the display panel may be about 0.5, a ratio of a length of an angle-customized display region (i.e., the second display region A2) closer to the center of the display panel to the length of the display region of the display panel may be about 0.75, and a ratio of a length of an angle-customized display region (third display region A3) farther from the center of the display panel to the length of the display region of the display panel may be about 1.

In an exemplary embodiment, taking a case that the display panel is applied to a display solution such as AR/VR which has higher requirements on display brightness and resolution as an example, a lens may be disposed on a light exit side of the display panel, then the metasurface device in the angle-customized display region is also configured such that deflected light is incident to the lens located on the light exit side of the display panel, wherein, a customized angle corresponding to the angle-customized display region may satisfy following equations (1) to (2).

$${θ}_{X} = {tan}^{- 1} \frac{{L}_{1 X} ( 1 - {L}_{2} / {L}_{1} )}{{d}_{1}} \qquad equation ( 1 )$$

$${θ}_{Y} = {tan}^{- 1} \frac{{L}_{1 Y} ( 1 - {L}_{2} / {L}_{1} )}{{d}_{1}} \qquad equation ( 2 )$$

Herein, θ_{X} represents a deflection angle of light in an x direction, θ_{Y} represents a deflection angle of light in the y direction, (L_{1X}, L_{1Y}) represents coordinates of a sub-pixel in the angle-customized display region, L₁ represents a length of the display region of the display panel, L₂ represents a diameter of the lens, and d₁ represents a distance between the lens and the display panel.

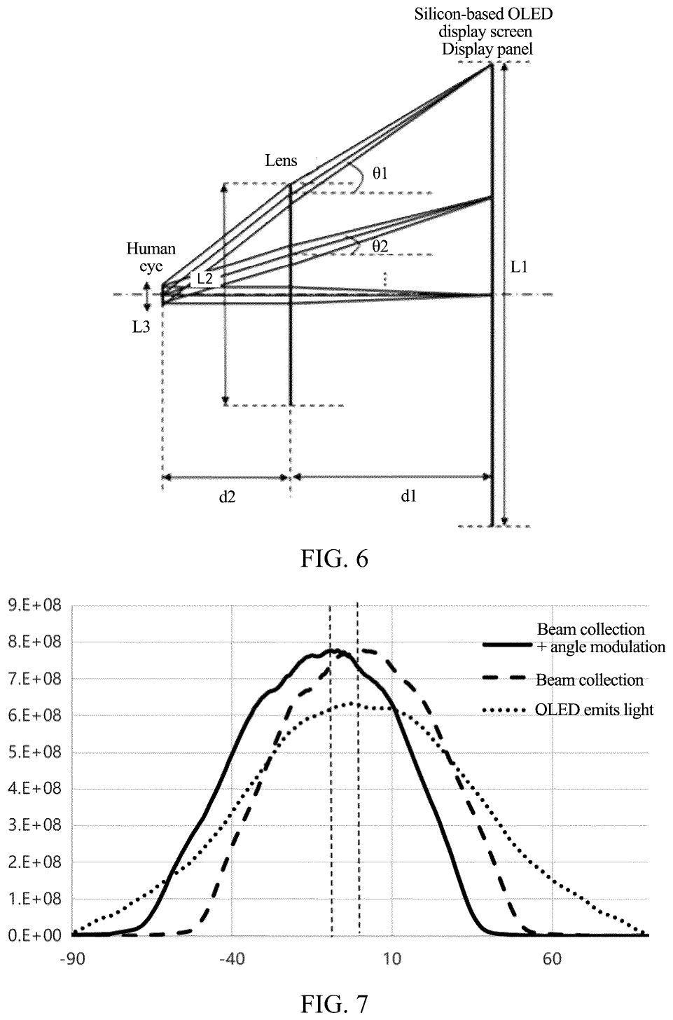

For example, as shown in FIGS. 5 and 6, taking a case that a side length of the display region AA is L₁, and the first display region A1, the second display region A2, and the third display region A3 are all square as an example, a side length of the first display region A1 may be about L_{1/2}, a side length of the second display region A2 may be about 3L_{1/4}, and a side length of the third display region A3 may be about L₁. Then, a customized angle corresponding to the second display region A2 may be approximately the second deflection angle

$${θ}_{2} = {tan}^{- 1} \frac{( {L}_{1} - {L}_{2} ) / 4}{{d}_{1}} ,$$

a customized angle corresponding to the third display region A3 may be approximately the first deflection angle

$${θ}_{1} = {tan}^{- 1} \frac{( {L}_{1} - {L}_{2} ) / 2}{{d}_{1}} .$$

Among them, L₁ represents the length of the display region of the display panel, L₂ is the diameter of the lens, and d₁ is the distance between the lens and the display panel.

In an exemplary embodiment, taking a case that the display panel is applied to a display solution such as AR/VR which has higher requirements on display brightness and resolution as an example, a light emitting angle of a sub-pixel has a maximum energy utilization rate within a range

$$\pm φ = {tan}^{- 1} \frac{{L}_{3} / 2}{{d}_{1}} ,$$

wherein L₃ is a diameter of a human eye, d₁ is the distance between the lens and the display panel.

In an exemplary embodiment, in a plane parallel to the display panel, a shape of the first display region A1 may be any one or more of following: a rectangle, a polygon, a circle, and an ellipse.

In an exemplary embodiment, in a plane parallel to a display panel, a shape of the second display region may be any one or more of following: a rectangular ring, a polygonal ring, a circular ring, and an elliptical ring.

In an exemplary embodiment, the metasurface device in the angle-customized display region may satisfy a following phase equation.

$$φ ( x , y ) = - 2 π n ( \sqrt{( {x}^{2} + {y}^{2} ) + {f}^{2}} - f ) / λ + 2 π n ( x cos ϕ + y sin ϕ ) sin θ / λ \qquad equation ( 3 )$$

Herein, (x, y) represents coordinates of different position points on the metasurface device, the geometric center of the metasurface device is an origin of coordinates, φ(x, y) represents a phase at a position point (x, y) on the metasurface device, λ represents a wavelength of incident light, f represents a focal length of a lens when the metasurface device expresses a phase of a beam collection lens, ϕ represents a grating angle when the metasurface device expresses a phase of a deflection grating, and θ is the customized angle corresponding to the angle-customized display region. Therefore, based on a phase superposition control characteristic of the metasurface device, e expressions of the phase of beam collection lens and the phase of the deflection grating by the metasurface device may be combined, and phase information of the beam collection lens and phase information of the deflection grating of the metasurface device may be superimposed, thus achieving the metasurface device has expression characteristics of expressing the phase of the lens and the phase of the deflection grating. Therefore, when the metasurface device expresses the phase of the beam collection lens and the phase of the deflection grating, a light emitting angle of light may be deflected and adjusted on a basis that a sub-pixel corresponding to the metasurface device emits light to perform beam collection, so as to achieve light emitting energy concentration of a pixel, improve an energy utilization rate, and improve light emitting brightness. Here, the focal length f should meet a distance from a designed metasurface structure to a light emitting surface, so as to ensure that the beam collection lens is under an optimal beam collection condition.

In an exemplary embodiment, a front half of the phase equation −2πn(\sqrt{(x²+y²)+f²}−f)/λ may be expressed as the phase information of the beam collection lens. In a case that the wavelength λ of incident light and the focal length f of the metasurface device are constant, an absolute value of the phase of the lens is proportional to a radius of a position point on the metasurface device. In this way, the metasurface device is configured to narrow a light emitting angular spectrum of the incident light to achieve a modulation effect of light emitting convergence.

In an exemplary embodiment, a rear half of the phase equation 2πn(x cos ϕ+y sin ϕ)sin θ/λ may be expressed as the phase information of the deflection grating. In a case that the grating angle ϕ is certain, an absolute value of the phase of the deflection grating is proportional to a target deflection angle θ required by the sub-pixel corresponding to the metasurface device. For example, as shown in FIG. 5, the third display region A3 is farther from the geometric center of the display panel, and the second display region A2 is closer to the geometric center of the display panel, so that a light deflection angle required by a sub-pixel of the third display region A3 is larger than a light deflection angle required by a sub-pixel of the second display region A2, thus a phase of a deflection grating of a metasurface device corresponding to the sub-pixel of the third display region A3 is larger than a phase of a deflection grating of a metasurface device corresponding to the sub-pixel of the second display region A2. In this way, it may be achieved that a light emitting angular spectrum of incident light is deflected and adjusted by the metasurface device, and light emitting energy concentration of a pixel is achieved.

For example, taking a case that an OLED is adopted for a sub-pixel as an example, as shown in FIG. 7, a first dashed line (discontinuous line drawn by dots) is used for illustrating an OLED light emitting angular spectrum, a second dashed line (discontinuous line drawn by short lines) is used for illustrating a light type change of the OLED light emitting angular spectrum modulated through the phase information of the beam collection lens, and a solid line is used for illustrating a light type change of the OLED light emitting angular spectrum modulated through the phase information of the beam collection lens and the phase information of the deflection grating simultaneously. By comparison, it may be seen that when the metasurface device only expresses the phase of the beam collection lens, it may be achieved that the OLED light emitting angular spectrum is narrowed (i.e., the beam collection function) after light passes through the metasurface device, so that a half peak of the light emitting angular spectrum is reduced from ±45° to ±30°, and brightness of a central viewing field angle may be improved by about 1.3 times. When the metasurface device expresses the phase of the beam collection lens and the phase of the deflection grating by means of superimposition, taking the customized angle θ=10° corresponding to the angle-customized display region where a sub-pixel is designed as an example, after light emitted by a light emitting device in the sub-pixel passes through a corresponding metasurface device, a beam center is compared with an original light type, a light emitting angular spectrum is deflected by about 10° after beam collection, thus achieving purposes of OLED light emitting beam collection and light emitting angle adjustment and control.

In an exemplary embodiment, a metasurface unit may be a metal microstructure or a dielectric microstructure a base substrate with a size smaller than a wavelength constructed on a base substrate. For example, a material of the base substrate may be Silicon Oxide (SiOx), and a material of the dielectric microstructure may be an oxide such as Silicon Nitride (SiNx) or Titanium dioxide (TiO2), and there is a large refractive index difference between the base substrate and the dielectric microstructure. For example, a refractive index difference between silicon oxide and silicon nitride may be greater than or equal to 0.5. For example, the dielectric microstructure may be a post body.

Phase modulation of the metasurface unit may include transmission phase type metasurface modulation, which introduces an equivalent refractive index change to form phase relay based on different unit structure scale changes (including a height, a width, or a diameter, etc.), geometric type metasurface modulation, which introduces a polarization component electromagnetic field phase difference based on a same unit structure and different rotation angles, and a hybrid phase modulation principle achieved by combining the transmission phase type metasurface modulation and the geometric type metasurface modulation. Among them, the phase modulation of the metasurface unit based on a transmission-type phase design may be understood as that phases caused by light transmission within structures with different depth-width ratios are different.

In an exemplary embodiment, a phase change caused by light transmission within the metasurface unit is proportional to an equivalent refractive index of the metasurface unit and a propagation distance. For a metasurface unit with a nano-post structure, an equivalent refractive index of the metasurface unit changes immediately when a radius of a nano-post changes. Therefore, a phase relay value of light passing through the metasurface unit may be adjusted by adjusting the radius of the nano-post.

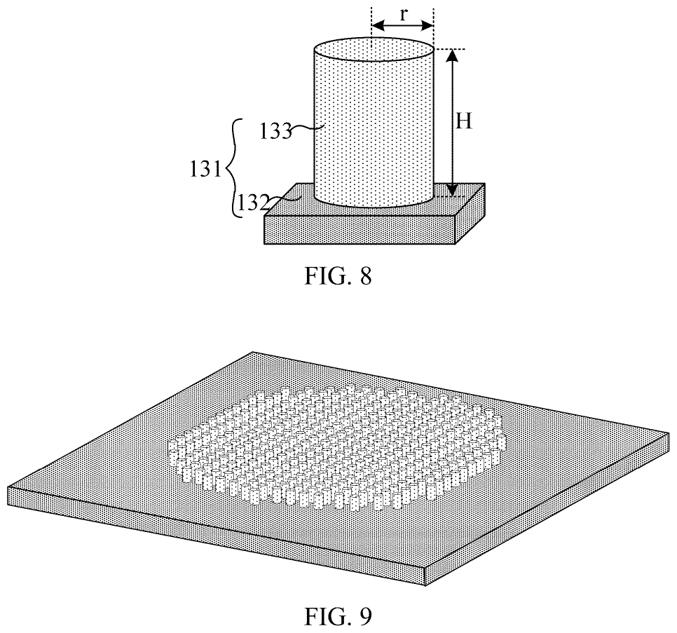

FIG. 8 is a schematic diagram of a structure of a metasurface unit according to an exemplary embodiment of the present disclosure, and FIG. 9 is a schematic diagram of a structure of a metasurface device according to an exemplary embodiment of the present disclosure. As shown in FIGS. 8 to 9, in one exemplary embodiment, a metasurface device 13 may include a plurality of metasurface units 131 regularly arranged in a unit period P, and at least one metasurface unit 131 may include a base substrate 132 and a post body 133 disposed on the base substrate 132, a refractive index of the base substrate 132 is different from that of the post body 133. For example, the base substrate 132 may be made of Silicon Dioxide (SiO2), and the post body 133 may be made of Silicon Nitride (SiNx). For example, a refractive index difference between Silicon Oxide (SiOx) and Silicon Nitride (SiNx) may be greater than or equal to 0.5. For example, for a metasurface device 13, base substrates 132 of all metasurface units 131 may be connected together to be a common layer.

In an exemplary embodiment, the post body 133 may include, but is not limited to, a cylinder, an elliptical cylinder, a triangular cylinder, a rectangular cylinder, or a polygonal cylinder, or the like. Among them, in FIGS. 8 to 9, illustrations are performed by taking a case that a cylinder is adopted for the post body 133 as an example. Here, no limitation is made thereto in embodiments of the present disclosure.

In an exemplary embodiment, taking a case that a cylinder is adopted for the post body 133 as an example, in at least one metasurface device, a radius r of the cylinder may be about 50 nm to 90 nm; or, the radius r of the cylinder may be about 55 nm to 110 nm; or, the radius r of the cylinder may be about 55 nm to 140 nm, etc. For example, in a metasurface device in a sub-pixel having a light emitting center wavelength of 450 nm, the radius r of the cylinder may be about 50 nm, 55 nm, 65 nm, 70 nm, 75 nm, 80 nm, 85 nm, or 90 nm, etc. For example, in a metasurface device in a sub-pixel having a light emitting center wavelength of 532 nm, the radius r of the cylinder may be about 55 nm, 65 nm, 75 nm, 85 nm, 90 nm, 100 nm, 105 nm, or 110 nm, etc. For example, in a metasurface device in a sub-pixel having a light emitting center wavelength of 620 nm, the radius r of the cylinder may be about 55 nm, 75 nm, 85 nm, 100 nm, 110 nm, 120 nm, 130 nm, or 140 nm, etc. Here, no limitation is made thereto in embodiments of the present disclosure.

In an exemplary embodiment, a height H of the post body 133 may be about 600 nm to 1000 nm. For example, the height of the post body 133 may be about 600 nm, 650 nm, 700 nm, 750 nm, 800 nm, 850 nm, 900 nm, 950 nm, or 1000 nm, etc. Here, no limitation is made thereto in embodiments of the present disclosure.

In an exemplary embodiment, the unit period P of the metasurface device may be about 200 nm to 300 nm. For example, in a metasurface device in a sub-pixel having a light emitting center wavelength of 450 nm, the unit period P may be about 225 nm. For example, in a metasurface device in a sub-pixel having a light emitting center wavelength of 532 nm, the unit period P may be about 250 nm. For example, in a metasurface device in a sub-pixel having a light emitting center wavelength of 620 nm, the unit period P may be about 300 nm. Among them, the unit period P may be a distance between geometric centers of two adjacent metasurface units. In this way, since different metasurface units have different phase relay values, by arranging a plurality of metasurface units with a set unit period P, corresponding metasurface devices may be constructed according to different phase modulation requirements.

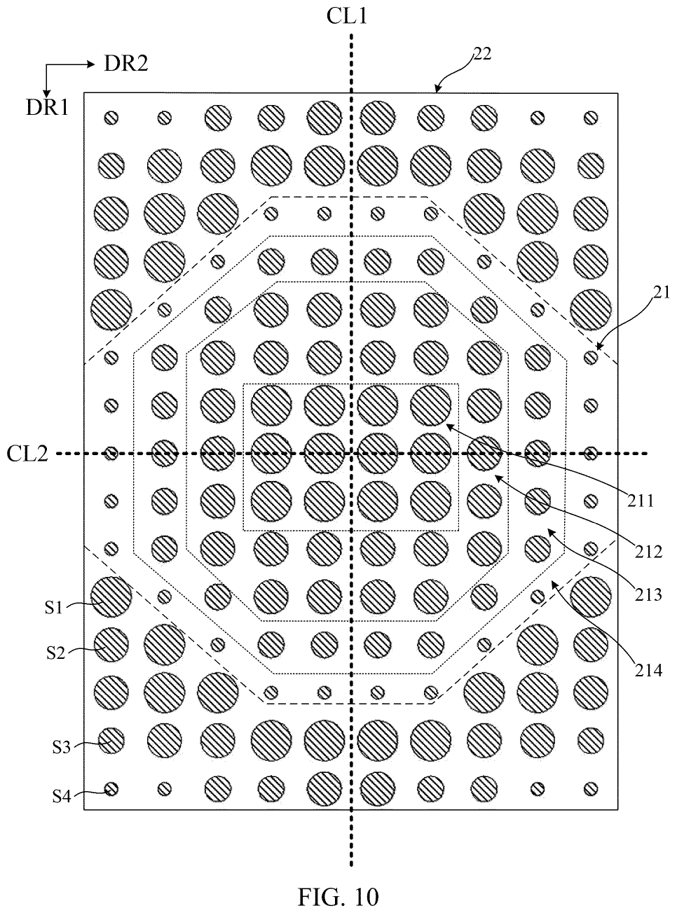

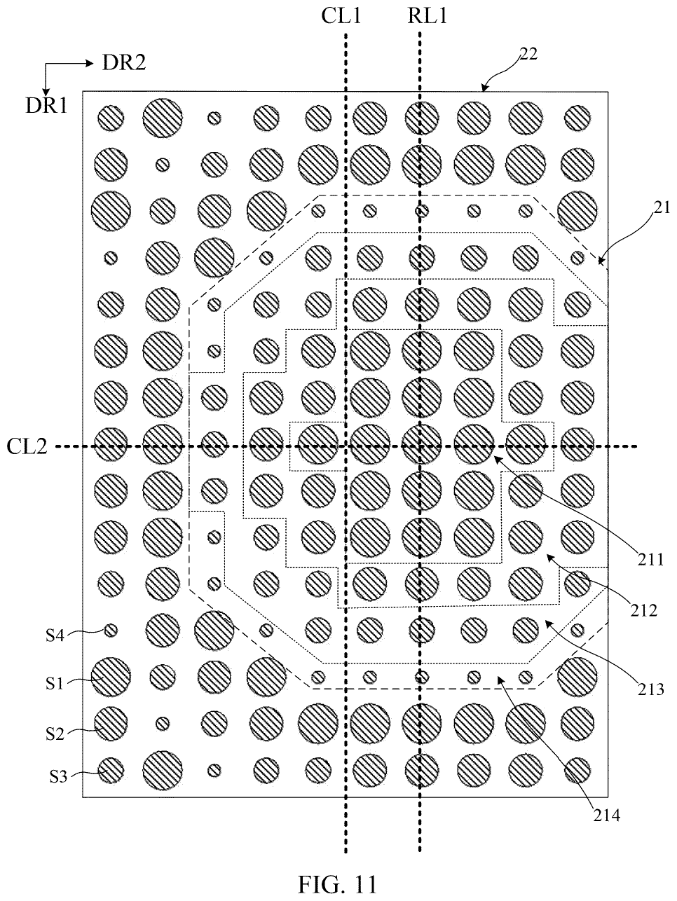

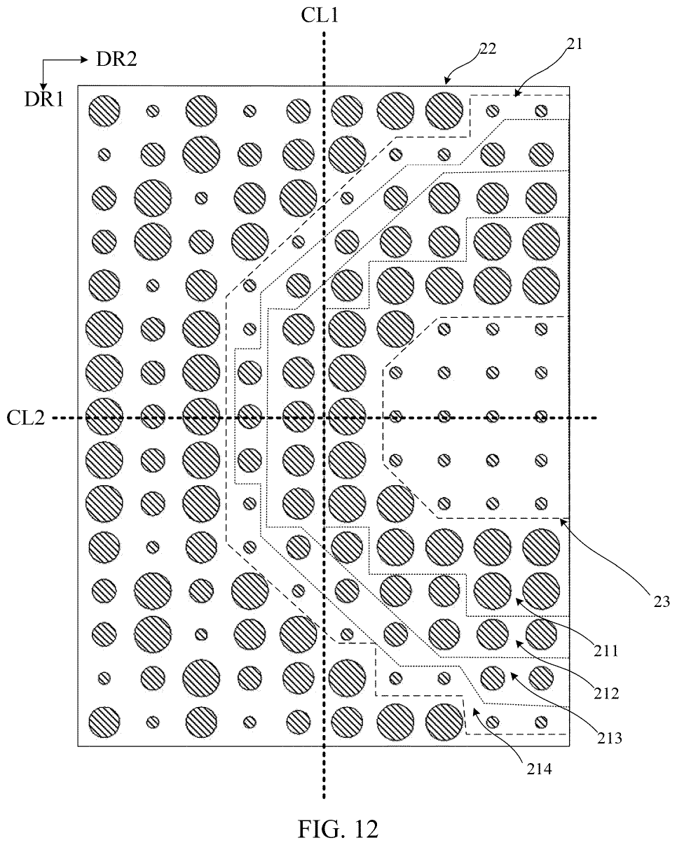

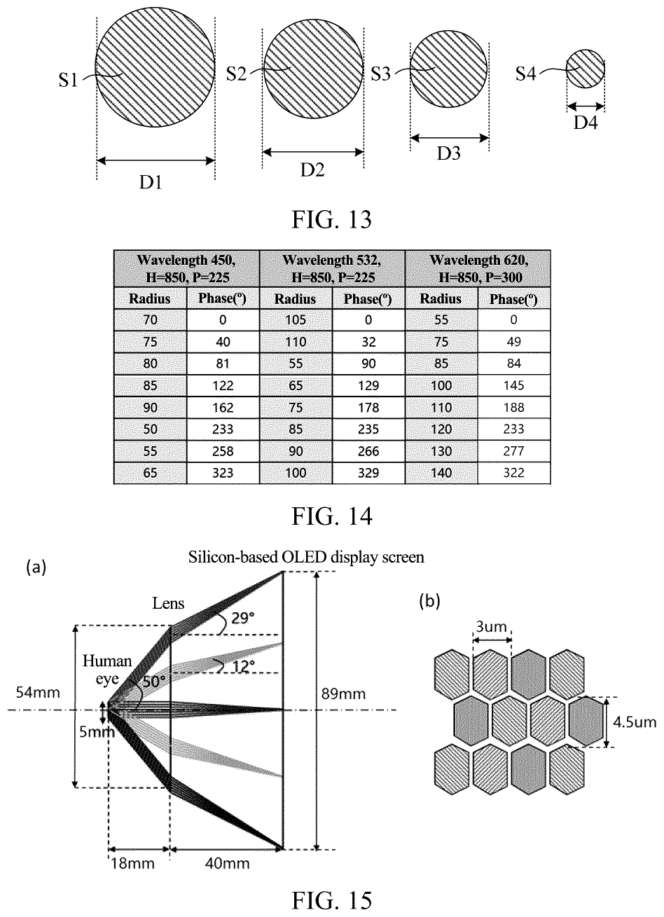

In an exemplary embodiment, taking a case that the display panel includes two angle-customized display regions as an example, along a direction away from a geometric center of the display panel, the display panel may include a central display region, a first angle-customized display region that at least partially surrounds the central display region, and a second angle-customized display region that at least partially surrounds the first angle-customized display region. FIG. 10 is a schematic diagram of a structure of a metasurface device of a central display region according to an exemplary embodiment of the present disclosure, FIG. 11 is a schematic diagram of a structure of a metasurface device of a first angle-customized display region according to an exemplary embodiment of the present disclosure, and FIG. 12 is a schematic diagram of a structure of a metasurface device of a second angle-customized display region according to an exemplary embodiment of the present disclosure. Among them, in FIGS. 10 to 12, illustrations are performed by taking a case that four metasurface units with different diameters are adopted for the metasurface device as an example.

In an exemplary embodiment, in the central display region, a pixel opening region of each sub-pixel may have a first center line CL1 extending along a first direction DR1 or a second center line CL2 extending along a second direction DR2. In each sub-pixel, a plurality of metasurface units of a metasurface device are disposed symmetrically with respect to one or more of a geometric center of the sub-pixel, the first center line CL1, and the second center line CL2. The second direction DR2 intersects with the first direction DR1, and an intersection point of the first center line CL1 and the second center line CL2 is a geometric center of the sub-pixel. For example, as shown in FIG. 10, for each sub-pixel in the central display region, a plurality of metasurface units in the sub-pixel may be symmetrically disposed with respect to a first center line CL1 of the sub-pixel. For example, as shown in FIG. 10, for each sub-pixel in the central display region, a plurality of metasurface units in the sub-pixel may be symmetrically disposed with respect to a first center line CL1 of the sub-pixel. For example, as shown in FIG. 10, for each sub-pixel in the central display region, a plurality of metasurface units in the sub-pixel may be disposed symmetrically with respect to a geometric center of the sub-pixel. Here, no limitation is made thereto in embodiments of the present disclosure.

In an exemplary embodiment, in at least one angle-customized display region, a pixel opening region of each sub-pixel may have a first reference line RL1 extending along a first direction DR1 or a second reference line RL2 extending along a second direction DR2, and at least a part of a plurality of metasurface units in each sub-pixel are symmetrically disposed with respect to a reference line extending along the first direction DR1 or a reference line extending along the second direction DR2. For example, the second center line CL2 may serve as the second reference line RL2. For example, as shown in FIG. 11, in the first angle-customized display region, a part of a plurality of metasurface units in each sub-pixel are symmetrically disposed with respect to the first reference line RL1 extending along the first direction DR1. For example, as shown in FIG. 11, in the first angle-customized display region, the second center line CL2 serves as the second reference line RL2, and a plurality of metasurface units in each sub-pixel are symmetrically disposed with respect to the second center line CL2 extending along the second direction DR2. For example, as shown in FIG. 12, in the second angle-customized display region, in the first angle-customized display region, the second center line CL2 serves as the second reference line RL2, and a plurality of metasurface units in each sub-pixel are symmetrically disposed with respect to the second center line CL2 extending along the second direction DR2.

In an exemplary embodiment, as shown in FIGS. 10 to 12, pixel opening regions of sub-pixels in the central display region and an angle-customized display region may each include a first region 21, the first region 21 may include a plurality of sub-regions, a diameter of a metasurface units in a sub-region farther from a geometric center of a sub-pixel in the plurality of sub-regions is smaller, or a diameter of a metasurface units in a sub-region farther from a geometric center of the first region 21 in the plurality of sub-regions is smaller. For example, a diameter of a metasurface unit in a sub-region farther from a geometric center of a sub-pixel in a plurality of sub-regions of the first region 21 in the central display region is smaller, or a diameter of a metasurface unit in a sub-region farther from a geometric center of the first region 21 in a plurality of sub-regions of the first region 21 in the angle-customized display region is smaller. For example, a geometric center of a sub-pixel may refer to a geometric center of a pixel opening region of the sub-pixel. For example, as shown in FIG. 10, on a straight line that passes through a geometric center of a sub-pixel and extends along a direction away from the geometric center of the sub-pixel (e.g., the first center line CL1, the second center line CL2, or a straight line that passes through the geometric center of the sub-pixel and crosses the second center line CL2, etc.), a distance between ae sub-region and a geometric center of a sub-pixel may refer to a distance between an outer contour edge of the sub-region and the geometric center of the sub-pixel. For example, as shown in FIG. 11, on a straight line that passes through a geometric center of the first region 21 and extends along a direction away from the geometric center of the first region 21 (e.g., the first reference line RL1, or a straight line that passes through the geometric center of the first region 21 and crosses the second center line CL2, etc.), a distance between a sub-region and the geometric center of the first region 21 may refer to a distance between an outer contour edge of the sub-region and the geometric center of the first region 21.

In an exemplary embodiment, as shown in FIGS. 10 to 12, a plurality of sub-regions in a first region 21 in a pixel opening region of a sub-pixel in the central display region and an angle-customized display region may each include four sub-regions, the four sub-regions may include a first sub-region 211, a second sub-region 212, a third sub-region 213, and a fourth sub-region 214. Along a direction away from the first region 21, the second sub-region 212 may be located on at least one side of the first sub-region 211, the third sub-region 213 is located on at least one side of the second sub-region 212, and the fourth sub-region 214 is located on at least one side of the third sub-region 213. For example, as shown in FIG. 10, in a first region 21 in a pixel opening region of a sub-pixel in the central display region 10, the first sub-region 211 may be located at a middle position of the first region 21, the second sub-region 212 may peripherally surround the first sub-region 211, the third sub-region 213 may peripherally surround the second sub-region 212, and the fourth sub-region 214 may peripherally surround the third sub-region 213. For example, as shown in FIG. 11, in a first region 21 in a pixel opening region of a sub-pixel in the first angle-customized display region, the first sub-region 211 may be located at a middle position of the first region 21, the second sub-region 212 may peripherally surround the first sub-region 211, the third sub-region 213 may surround an upper side, a lower side, and a left side of the second sub-region 212, and the fourth sub-region 214 may surround an upper side and a lower side of the third sub-region 213. For example, as shown in FIG. 12, in a first region 21 in a pixel opening region of a sub-pixel in the second angle-customized display region, the first sub-region 211 may be located on a right side of the first region 21, the second sub-region 212 may surround an upper side, a lower side, and a left side of the first sub-region 211, the third sub-region 213 may surround an upper side, a lower side, and a left side of the second sub-region 212, and the fourth sub-region 214 may surround an upper side and a lower side of the third sub-region 213.

In an exemplary embodiment, as shown in FIGS. 10 to 12, a distance between an contour edge of the fourth sub-region 214 and a geometric center of a sub-pixel is greater than a distance between an contour edge of the third sub-region 213 and the geometric center of the sub-pixel, a distance between the contour edge of the third sub-region 213 and the geometric center of the sub-pixel is greater than a distance between an contour edge of the second sub-region 212 and the geometric center of the sub-pixel, and a distance between the contour edge of the second sub-region 212 and the geometric center of the sub-pixel is greater than a distance between an contour edge of the first sub-region 211 and the geometric center of the sub-pixel.

In an exemplary embodiment, as shown in FIGS. 10 to 12, the first sub-region 211 may include a plurality of first metasurface units S1, the second sub-region 212 may include a plurality of second metasurface units S2, the third sub-region 213 may include a plurality of third metasurface units S3, and the fourth sub-region 214 may include a plurality of fourth metasurface units S4, wherein a diameter D1 of a first metasurface unit S1 is greater than a diameter D2 of a second metasurface unit S2, the diameter D2 of the second metasurface unit S2 is greater than a diameter D3 of a third metasurface unit S3, and the diameter D3 of the third metasurface unit S3 is greater than a diameter D4 of a fourth metasurface unit S4.

In an exemplary embodiment, as shown in FIGS. 10 to 12, a dimension of a first sub-region 211 in a pixel opening region of a sub-pixel in the first angle-customized display region in the first direction DR1 is larger than a dimension of a first sub-region 211 in a pixel opening region of a sub-pixel in the central display region in the first direction DR1, and a dimension of a first sub-region 211 in a pixel opening region of a sub-pixel in the second angle-customized display region in the first direction DR1 is larger than the dimension of the first sub-region 211 in the pixel opening region of the sub-pixel in the first angle-customized display region in the first direction DR1. In an exemplary embodiment, as shown in FIGS. 10 to 12, a dimension of the first sub-region 211 in the pixel opening region of the sub-pixel in the first angle-customized display region in the second direction DR2 is larger than a dimension of the first sub-region 211 in the pixel opening region of the sub-pixel in the central display region in the second direction DR2, and a dimension of the first sub-region 211 in the pixel opening region of the sub-pixel in the second angle-customized display region in the second direction DR2 is larger than the dimension of the first sub-region 211 in the pixel opening region of the sub-pixel in the first angle-customized display region in the second direction DR2.

In an exemplary embodiment, as shown in FIGS. 10 to 12, a distance between a geometric center of a sub-region where a metasurface unit with a largest diameter is located in a plurality of sub-regions in the central display region and a geometric center of a sub-pixel is a first distance, a distance between a geometric center of a sub-region where a metasurface unit with a largest diameter in a plurality of sub-regions in an angle-customized display region and the geometric center of the sub-pixel is a second distance, and the first distance is less than the second distance. For example, as shown in FIGS. 10 to 12, among a plurality of sub-regions in pixel opening regions of sub-pixels in the central display region, the first angle-customized display region, and the second angle-customized display region, a first sub-region 211 may be used as a sub-region where a metasurface unit with a largest diameter is located, a distance between a geometric center of a first sub-region 211 in the central display region and a geometric center of a corresponding sub-pixel is smaller than a distance between a geometric center of a first sub-region 211 in the first angle-customized display region and a geometric center of a corresponding sub-pixel, and the distance between the geometric center of the first sub-region 211 in the central display region and the geometric center of the corresponding sub-pixel is smaller than a distance between a geometric center of a first sub-region 211 in the second angle-customized display region and a geometric center of a corresponding sub-pixel.

In an exemplary embodiment, as shown in FIG. 10, a geometric center of at least one of a plurality of sub-regions in a pixel opening region of a sub-pixel in the central display region coincides with a geometric center of the sub-pixel. For example, as shown in FIG. 10, in a plurality of sub-regions in a pixel opening region of a sub-pixel in the central display region, a geometric center of a sub-region (e.g., a first sub-region 211) where a metasurface unit with a largest diameter is located coincides with the geometric center of the sub-pixel. For example, as shown in FIG. 10, in a plurality of sub-regions in a pixel opening region of a sub-pixel in the central display region, a geometric center of a sub-region (e.g., a fourth sub-region 214) where a metasurface unit with a smallest diameter is located coincides with a geometric center of the sub-pixel. For example, as shown in FIG. 10, in a plurality of sub-regions in a pixel opening region of a sub-pixel in the central display region, a geometric center of another sub-region (e.g., a second sub-region 212 or a third sub-region 213) located between a sub-region where a metasurface unit with a largest diameter is located (e.g., a first sub-region 211) and a sub-region where a metasurface unit with a smallest diameter is located (e.g., a fourth sub-region 214) coincides with a geometric center of the sub-pixel.

In an exemplary embodiment, as shown in FIGS. 11 and 12, in a plurality of sub-regions of a first sub-region in a pixel opening region of a sub-pixel in at least one angle-customized display region, a distance between a geometric center of a sub-region where a metasurface unit with a largest diameter is located and a geometric center of the sub-pixel is a non-zero distance. That is, in a plurality of sub-regions in the pixel opening region of the sub-pixel in at least one angle-customized display region, the geometric center of the sub-region where the metasurface unit with the largest diameter is located does not coincide with the geometric center of the sub-pixel. For example, the non-zero distance may be greater than a pitch between two adjacent metasurface units. For example, the pitch between two adjacent metasurface units may refer to a distance between geometric centers of two adjacent metasurface units, such as a distance between geometric centers of two adjacent metasurface units with a largest diameter. For example, as shown in FIG. 11, among a plurality of sub-regions in a pixel opening region of a sub-pixel in the first angle-customized display region, a first sub-region 211 may be used as a sub-region where a metasurface unit with a largest diameter is located, a geometric center of the first sub-region 211 is an intersection point between a first reference line RL1 and a second reference line RL2 (i.e., a second center line CL2), a geometric center of the sub-pixel may be an intersection point between a first center line CL1 and the second center line CL2, the geometric center of the first sub-region 211 is located on a side of the geometric center of the sub-pixel in the second direction DR2, there is a non-zero distance between the geometric center of the first sub-region 211 and the geometric center of the sub-pixel, the non-zero distance may be greater than a pitch between two adjacent metasurface units with a largest diameter, that is, the geometric center of the first sub-region 211 in the pixel opening region of the sub-pixel in the first angle-customized region 11 does not coincide with the geometric center of the sub-pixel.

In an exemplary embodiment, as shown in FIGS. 10 to 12, in at least one angle-customized display region, a pixel opening region of each sub-pixel has a first reference line RL1 extending along the first direction DR1 or a second reference line RL2 extending along the second direction DR2, and in a plurality of sub-regions of a first region 21 in at least one angle-customized display region, metasurface units in at least one sub-region are symmetrically disposed with respect to at least one of the first reference line RL1 and the second reference line RL2. For example, as shown in FIG. 11, metasurface units in a first sub-region 211 of the first angle-customized display region may be symmetrically disposed with respect to the first reference line RL1 extending along the first direction DR1. For example, as shown in FIG. 11, in the first angle-customized display region, metasurface units in a first sub-region 211, a second sub-region 212, a third sub-region 213, and a fourth sub-region 214 may be symmetrically disposed with respect to a center line CL2 extending along the second direction DR2. For example, as shown in FIG. 12, in the second angle-customized display region, metasurface units in a first sub-region 211, a second sub-region 212, a third sub-region 213, and a fourth sub-region 214 may be symmetrically disposed respect to a center line CL2 extending along the second direction DR2.

In an exemplary embodiment, as shown in FIGS. 10 to 12, the pixel opening areas of the sub-pixels in the central display region 10 and the angle-customized display region 11 may each further include a second region 22 that at least partially surrounds the first region 21, and a diameter of a metasurface unit in a region close to the first region 21 in the second region 22 is larger than a diameter of a metasurface unit in a region close to the second region 22 in the first region 21. For example, as shown in FIG. 10, in the central display region 10, the second region 22 may surround the first region 21, and a diameter of a metasurface unit in a region farther from a geometric center of a sub-pixel in the second region 22 is smaller. For example, as shown in FIG. 11, in the first angle-customized display region, a second region 22 may be disposed on an upper side, a lower side, and a left side of a first region 21, and a diameter of a metasurface unit in a partial region farther from the second center line CL2 in the second region 22 is smaller. For example, as shown in FIG. 12, in the first angle-customized display region, the second region 22 may be disposed on the left side of the first region 21.

In an exemplary embodiment, as shown in FIG. 12, a pixel opening region of a sub-pixel in the second angle-customized display region may include a third region 23 located on a side of the first region 21 away from the second region 22, for example, in the second angle-customized display region, the second region 22 may be located on an upper side, a lower side, and a left side of the third region 23. For example, in the second angle-customized display region, a diameter of a metasurface unit in a region close to the first region 21 in the third region 23 is smaller than a diameter of a metasurface unit in a region close to the third region 23 in the first region 21, and the diameter of the metasurface unit in the region close to the first region 21 in the third region 23 is smaller than a diameter of a metasurface unit in a region close to the first region 21 in the second region 22. For example, in the second angle-customized display region, a diameter of a metasurface unit in the third region 23 is smaller than a diameter of a metasurface unit in the first sub-region 211, and the diameter of the metasurface unit in the third region 23 is smaller than a diameter of a metasurface unit in the region close to the first region 21 in the second region 22.

In an exemplary embodiment, along a direction away from the geometric center of the display panel, the display panel may include N angle-customized display regions, wherein a distance between a geometric center of a sub-region where a metasurface unit with a largest diameter is located in a plurality of sub-regions in a pixel opening region of a sub-pixel in an N-th angle-customized display region and a geometric center of a corresponding sub-pixel is a third distance, a distance between a geometric center of a sub-region where a metasurface unit with a largest diameter is located in a plurality of sub-regions in a pixel opening region in a sub-pixel in an (N−1)-th angle-customized display region and a geometric center of a corresponding sub-pixel is a fourth distance, and the third distance is greater than the fourth distance, and N is a positive integer greater than 1. For example, as shown in FIGS. 11 to 12, among a plurality of sub-regions in a pixel opening region of a sub-pixel in the first angle-customized display region and the second angle-customized display region, a first sub-region 211 may be used as a sub-region where a metasurface unit with a largest diameter is located, and a distance between a geometric center of a first sub-region 211 in the second angle-customized display region and a geometric center of a corresponding sub-pixel is greater than a distance between a geometric center of a first sub-region 211 in the first angle-customized display region and a geometric center of a corresponding sub-pixel.

In an exemplary embodiment, along a direction away from the geometric center of the display panel, the display panel includes N angle-customized display regions, wherein a customized angle corresponding to an N-th angle-customized display region is greater than a customized angle corresponding to an (N−1)-th angle-customized display region, and N is a positive integer greater than 1. For example, a customized angle corresponding to the second angle-customized display region is larger than a customized angle corresponding to the first angle-customized display region.

In an exemplary embodiment, a phase change of a light field is a continuous change between 2π (360° phase change). By traversing parameters of metasurface units, a plurality of metasurface units containing 2π phase change at different wavelengths may be obtained to form an infrastructure database, the infrastructure database contains post structures with different heights and radii and phase information corresponding to these post structures respectively, and the phase information covers a range from 0 to 2π. Corresponding metasurface devices may be constructed for different phase modulation requirements by using the infrastructure database.

In an exemplary embodiment, in order to simplify computational complexity of constructing the metasurface device and improve an efficiency of constructing the metasurface device, a metasurface unit structure library may be constructed on a basis of the infrastructure database. The metasurface unit structure library contains post structures with a same height and n radii, and basic phase information corresponding to the n post structures respectively. A corresponding metasurface device may be constructed by using the metasurface unit structure library, and n may be a positive integer greater than or equal to 2.

In an exemplary embodiment, within a range of phases from 0 to 2π, phase division may be performed according to a phase step of π/4, and eight basic phases are obtained and are respectively: 0, π/4, π/2, 3π/4, π, 5π/4, 3π/2, and 7π/4. Eight post structures corresponding to eight basic phases are selected from the infrastructure database, so as to construct the metasurface unit structure library. Therefore, the metasurface unit structure library contains eight basic phases and post structures corresponding to the eight basic phases.

In an exemplary embodiment, the smaller the phase step is, the finer the obtained metasurface unit structure library is, but the more complicated the calculation and machining is. Choosing a phase step of π/4 may not only ensure that the metasurface device may cover required phase information, but also facilitate calculation and subsequent process fabrication. In an exemplary embodiment, phase steps may be the same or may be different, which is not limited in the present disclosure.

In an exemplary embodiment, since different metasurface units have different phase relay values, by arranging a plurality of metasurface units at a set unit period P, corresponding metasurface devices may be constructed according to different angle-customized requirements.

In an exemplary embodiment, the metasurface unit structure library may be constructed according to an OLED pixel light emitting center wavelength. For example, a metasurface structure layer may be constructed by using metasurface structure units with corresponding wavelengths corresponding to different light emitting colors. For example, for a monochromatic device, a same group of structure units may be adopted for structural design and construction.

In an exemplary embodiment, FIG. 14 is a schematic diagram of parameters of a metasurface unit structure library according to an exemplary embodiment of the present disclosure, in FIG. 14, it is illustrated by taking parameters of a plurality of metasurface units in a metasurface device in sub-pixels with wavelengths of 450 nm, 532 nm, and 620 nm as an example. As shown in FIG. 10, for a light emitting center wavelength of each sub-pixel, the metasurface unit structure library may include eight basic phases and metasurface units in a shape of post structures corresponding to the eight basic phases. Among them, in a first metasurface unit structure library (corresponding to a sub-pixel with a light emitting center wavelength of 450 nm), eight metasurface units include: SiNx nano-posts with a height H of 850 nm and radii of 70 nm, 75 nm, 80 nm, 85 nm, 90 nm, 50 nm, 55 nm, and 65 nm respectively on a SiO2 base substrate. A unit period P of the metasurface device is 225 nm, and basic phases of the eight metasurface units are 0°, 40°, 81°, 122°, 162°, 233°, 258°, and 323° respectively. In a second metasurface unit structure library (corresponding to a sub-pixel with a light emitting center wavelength of 532 nm), eight metasurface units include: SiNx nano-posts with a height H of 850 nm and radii of 105 nm, 110 nm, 55 nm, 65 nm, 75 nm, 85 nm, 90 nm, and 100 nm respectively on a SiO2 base substrate. A unit period P of the metasurface device is 250 nm, and basic phases of the eight metasurface units are 0°, 32°, 90°, 129°, 178°, 235°, 266°, and 329° respectively. In a third metasurface unit structure library (corresponding to a sub-pixel with a light emitting center wavelength of 620 nm), eight metasurface units include: SiNx nano-posts with a height H of 850 nm and radii of 55 nm, 75 nm, 85 nm, 100 nm, 110 nm, 120 nm, 130 nm, and 140 nm respectively on a SiO2 base substrate. A unit period P of the metasurface device is 300 nm, and basic phases of the eight metasurface units are 0°, 49°, 84°, 145°, 188°, 233°, 277°, and 322° respectively.

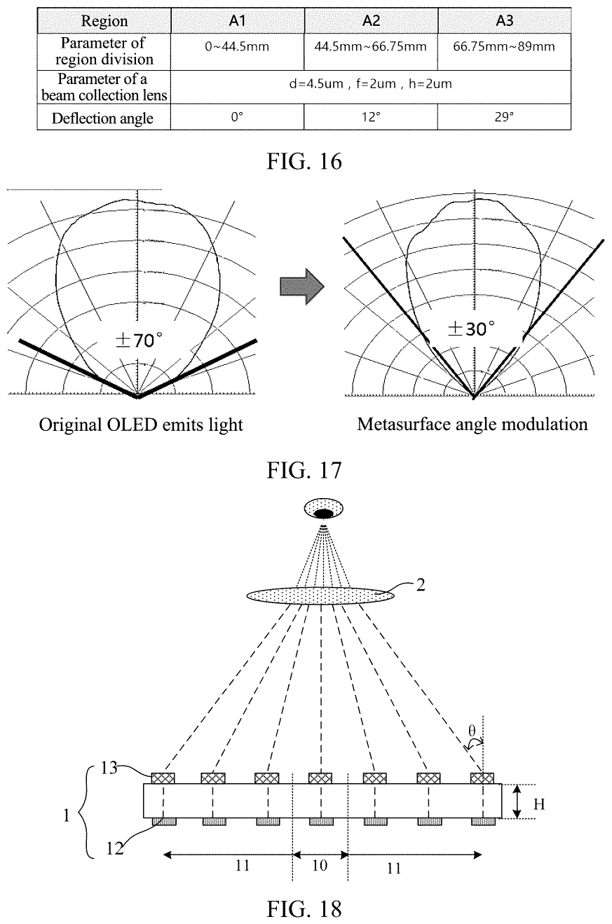

In an exemplary embodiment, referring to structures shown in FIGS. 5 and 6, taking parameters and pixel distribution of a silicon-based OLED VR display solution shown in FIG. 15 as an example, main design parameters may be obtained as shown in FIG. 16. According to a light emitting spectrum, an angular spectrum, and structural characteristics corresponding to an OLED, a metasurface unit whose a design morphology matches a pixel unit size (such as 3 um*4.5 um) under conditions of a placement height of 2.5 um (micron) (determined by a thickness of the encapsulation layer described above) and a medium refractive index of 1.5 is designed (parameters of a beam collection lens expressed by the metasurface unit may include: a diameter d is 4.5 um, a focal length f is 2 μm, and a placement height h is 2 um, etc.) to achieve beam collection of an OLED light source with a light emitting angle of ±70°. According to a size of an OLED display screen (for example, a side length of a display region L1=89 mm) and overall planning of a VR system, that is, light emitted by the OLED display screen needs to be optically modulated via a lens with a radial width L2 (for example, 54 mm) at a distance d1 (for example, 40 mm), and then enters a range of a human eye with a diameter L3 (for example, 5 mm) at a distance d2, a screen partition design is carried out, and a deflection angle of a light beam after beam collection is designed for a plurality of angle-customized display regions, a customized angle calculation equation is used and following calculated results may be obtained: a customized angle (e.g., a deflection angle) corresponding to a first display region A1 (which may be used as a central display region) is 0°, a customized angle (e.g., a deflection angle) corresponding to a second display region A2 (which may be used as a first angle-customized display region) is 12°, a customized angle (e.g., a deflection angle) corresponding to a third display region A3 (which may be used as a second angle-customized display region) is 29°. Then, phase distribution of a metasurface device corresponding to each pixel may be calculated by using a phase equation satisfied by a metasurface device in an angle-customized display region. Then, according to a construction method of a metasurface device, a modulated phase corresponding to each pixel is discretized and replaced, and a metasurface unit needed for constructing the metasurface device may be obtained. For example, taking an OLED pixel with a center wavelength of 532 nm as an example, according to a designed phase plane, a structure library is employed to build a structure plane after discretization, and the metasurface device shown in FIG. 10 may be obtained for the central display region, and metasurface devices shown in FIG. 11 and FIG. 12 may be obtained for two angle-customized display regions. In addition, division of the central display region and N angle-customized display regions in the display region of the display panel may be optimized to obtain a better modulation effect.

The inventor of the present disclosure performs simulation of a modulation result for a whole display panel, extracts angular brightness distribution before and after optimization, so as to obtain a schematic diagram of angular spectrum changes before and after adjustment and control of an OLED light emitting angle as shown in FIG. 17. From the simulation result shown in FIG. 17, it may be seen that a viewing field angle of an OLED light emitting device may be reduced from original ±70° to ±30° by using a metasurface device, at the same time, positive viewing angle brightness of the light emitting device may be increased by 1,3 times, thus achieving efficient utilization of light emitting energy of the whole light emitting device.

A preparation process of a metasurface device in a display panel according to an exemplary embodiment of the present disclosure is described below. It may be understood that methods commonly used in the art may be adopted for a preparation process of a base substrate and a light emitting device disposed on the base substrate and herein a preparation process of a metasurface structure layer will be described in detail. It may be understood that for “patterning” mentioned in the present disclosure, when a patterned material is an inorganic material or metal, the “patterning” includes a process such as photoresist coating, mask exposure, development, etching, and photoresist stripping, when the patterned material is an organic material, the “patterning” includes a process such as mask exposure and development, and evaporation, deposition, coating, and coating, etc., mentioned in the present disclosure are all mature preparation processes in the related art.

In an exemplary embodiment, an angle-customizable display panel based on a metasurface according to an embodiment of the present disclosure may be chosen to be processed by using a semiconductor lithography solution according to a high requirement of alignment accuracy.

In an exemplary embodiment, referring to a structure of the display panel shown in FIGS. 4A and 4B, a metasurface structure layer provided in the embodiment of the present disclosure may be constructed between an encapsulation layer (e.g., SiOx is adopted) and a cover plate layer (e.g., a glass cover plate) and device integration may be achieved by flattening. For example, taking a case that an OLED is adopted for a light emitting device as an example, a metasurface structure layer of actual mass production process may be directly integrated on a surface of the OLED by using a semiconductor lithography process. In this way, the display panel is facilitated to be thinner and lighter.

In an exemplary embodiment, the preparation process of the metasurface device in the display panel may include following acts.
(1) On a surface of an unencapsulated light emitting device, a thin film of an encapsulation material with a preset thickness is deposited to form an encapsulation layer. In this way, flattening and a placement height of a metasurface device may be ensured. For example, the thin film of the encapsulation material may be SiOx.
(2) A metasurface material thin film and a Hard Mask thin film are deposited on a surface of the encapsulation layer to construct a metasurface structure layer and a Hard Mask required for etching. For example, the metasurface material thin film may be SiNx. For example, a material of the hard mask thin film may be at least one of Aluminum (Al) and Titanium (Ti), and may also be another available material. Here, no limitation is made thereto in embodiments of the present disclosure.
(3) The hard mask thin film is patterned, so that the hard mask thin film forms a pattern of the metasurface device to form a hard mask layer. For example, a dedicated photoresist for Electron Beam direct-write Lithography (EBL), such as PolyMethylMethacrylate (PMML), may be coated on a surface of the hard mask thin film, and then the photoresist is exposed and developed by using electron beam direct-write lithography, and a reverse structure of the metasurface structure layer is processed on the photoresist, so that the photoresist forms a pattern consistent with a metasurface structure.
(4) The exposed hard mask thin film is etched through an etching process (such as a dry etching process), the structure on the photoresist is transferred to the hard mask thin film, a pattern of the metasurface structure layer is formed by the hard mask thin film to form a hard mask layer, and remaining photoresist is washed away.
(5) The metasurface material thin film is etched through an etching process (such as a dry etching process) to transfer the structure on the hard mask layer onto the metasurface material thin film, and the hard mask layer is removed, thereby obtaining a final metasurface structure layer, wherein the metasurface structure layer includes a metasurface device corresponding to the light emitting device, and the metasurface device includes a plurality of metasurface units.
(6) An encapsulation adhesive is coated at a gap between a plurality of metasurface devices in the metasurface structure layer to protect a structure of the metasurface devices, and then a cover plate layer (e.g., a glass cover plate) is encapsulated on the metasurface structure layer, thereby completing preparation of the display panel.

In addition, the display panel according to the embodiment of the present disclosure may further include other necessary components and structures, such as gate lines, data lines, and other components, in addition to structures listed above. Those skilled in the art may design and supplement the display panel accordingly according to a type of the display panel, which will not be repeated here.

An exemplary embodiment of the present disclosure also provides a construction method of a metasurface device. This method is applicable to the display panel in one or more of the above embodiments.

In an exemplary embodiment, the construction method of the metasurface device may include following acts.

Act S1: obtaining a customized angle corresponding to an angle-customized display region.

Act S2: determining phases of different position points on a metasurface device of each sub-pixel in the angle-customized display region according to the customized angle corresponding to the angle-customized display region.

Act S3: determining metasurface units at different regional positions on the metasurface device in each sub-pixel in the angle-customized display region according to the phases of different position points on the metasurface device of each sub-pixel in the angle-customized display region and a pre-established metasurface unit structure library.

Act S4: constructing the metasurface device of each sub-pixel in the angle-customized display region by using the metasurface units at different regional positions on the metasurface device of each sub-pixel in the angle-customized display region.

In an exemplary embodiment, the act S1 may include: act S11: determining a target deflection angle corresponding to each sub-pixel according to position information of each sub-pixel, a length of a display region of the display panel, a diameter of a lens, and a distance between the lens and the display panel.

In an exemplary embodiment, the act S11 may include: determining a customized angle corresponding to the angle-customized display region according to position information of each sub-pixel, the length of the display region of the display panel, the diameter of the lens, and the distance between the lens and the display panel by using angle equations shown in the above equation (1) and equation (2) satisfied by the customized angle corresponding to the angle-customized display region.

In an exemplary embodiment, the act S2 may include: determining the phases of different position points on the metasurface device in the angle-customized display region according to the customized angle corresponding to the display region by using the phase equation shown in the above equation (3) satisfied by the metasurface device in the angle-customized display region.

In an exemplary embodiment, the act S3 may include following acts.

Act S31: discretizing the phases of different position points on the metasurface device corresponding to each sub-pixel to obtain phases of different regions on the metasurface device corresponding to each sub-pixel.

Act S32: determining the metasurface units at different regional positions on the metasurface device corresponding to each sub-pixel according to the phases of different regions on the metasurface device corresponding to each sub-pixel and the pre-established metasurface unit structure library.

In an exemplary embodiment, the act S4 may include: by using the obtained metasurface units at different regional positions on the metasurface device corresponding to each sub-pixel, performing structure filling at different regional positions of the metasurface device corresponding to each sub-pixel, and constructing the metasurface device corresponding to each sub-pixel.

In this way, in the construction method of the metasurface device according to the exemplary embodiment of the present disclosure, phase distribution of the metasurface device is determined according to the customized angle corresponding to the angle-customized display region, a metasurface unit with a corresponding phase modulation value is selected from the metasurface unit structure library through calculating and discretizing the phase distribution of the metasurface device, and a metasurface device with a corresponding light deflection effect is constructed by using these metasurface units for filling arrangement, which may effectively avoid a structure error in processing and a design process of a traditional geometrical optical device, and may achieve a design of an optical device within a small scale range. Therefore, a constructed metasurface device with a corresponding light angle deflection effect is applied to the display panel, and a light emitting angle of light emitted by a light emitting device is deflected and adjusted at a customized angle through the metasurface device, so that light emitting energy concentration of the light emitting device may be achieved, an energy utilization rate of the light emitting device may be improved, a customization requirement of a light emitting angle of a sub-pixel may be achieved, and brightness enhancement within a range of a viewing angle may be achieved. Moreover, by constructing a metasurface device with light modulation characteristics in a sub-pixel, performance of a light emitting device may be improved, at the same time, it is beneficial to ensured thinness and lightness of the display panel. In this way, a high-performance display panel with high brightness, thinness, and a designable viewing field angle may be achieved. Furthermore, when the display panel is applied to a display solution having high requirements on display brightness and resolution, such as AR/VR, an energy utilization rate of a light emitting device within a usable field viewing angle range may be increased, and brightness enhancement within a viewing angle range may be achieved, which is beneficial to thinness of a near-eye display apparatus.

The above description of the embodiment of the method is similar to the above description of the embodiment of the display panel, and has similar beneficial effects as the embodiment of the display panel. Technical details undisclosed in the embodiment of the method of the present disclosure may be understood by those skilled in the art with reference to the description in the embodiment of the display panel of the present disclosure, which will not be repeated here.

An exemplary embodiment of the present disclosure also provides a near-eye display apparatus.

In an exemplary embodiment, the near-eye display apparatus according to the exemplary embodiment of the present disclosure may include, but is not limited to, a VR display apparatus, an AR display apparatus, or another apparatus or device having a near-eye display function, and a near-eye display apparatus which may achieve a high light efficiency, high brightness, a high resolution, and thinness.

FIG. 18 is a schematic diagram of a structure of a near-eye display apparatus according to an exemplary embodiment of the present disclosure. As shown in FIG. 18, the near-eye display apparatus may include a display panel 1 in one or more of the above-mentioned embodiments and a light modulation device 2 located on a light exit side of the display panel 1. The display panel 1 may include a central display region 10 and an angle-customized display region 11 surrounding the central display region 10. A metasurface device 13 in the angle-customized display region 11 is configured such that light emitted by a corresponding light emitting device 12 is deflected at a customized angle corresponding to the angle-customized display region 11 and incident to the light modulation device 2.

In an exemplary embodiment, the light modulation device 2 may include a lens. Here, an actual structure, a focal length, a diameter, and another parameter of the lens are subject to achievement of an application scenario, which is not limited in the embodiment of the present disclosure.

In an exemplary embodiment, a phase expressed by each metasurface device includes a phase of a beam collection lens and a phase of a light emitting angle deflection corresponding to a target deflection angle required by a sub-pixel, thus each metasurface device is configured to have light emitting shaping, a light emitting angular spectrum narrowing function, and a light emitting direction deflection function simultaneously. In this way, an energy utilization rate may be improved at two levels of light emission and collection.

In this way, the near-eye display apparatus in the exemplary embodiment of the present disclosure, a corresponding customized angle is designed for different angle-customized display regions and a metasurface device is disposed, a light emitting angle of light emitted by a corresponding light emitting device and the customized angle are deflected and adjusted through the metasurface device by using phase superposition adjustment and control characteristics of the metasurface device, deflection of an emitting direction of light may be achieved, so that deflected light may be incident to a light modulation device, and light emitting energy concentration of the light emitting device may be achieved, thereby improving an energy utilization rate of the light emitting device and achieving a customization requirement of a light emitting angle of a sub-pixel. Moreover, by constructing a metasurface device with light modulation characteristics in a sub-pixel, performance of the light emitting device may be improved, at the same time, it is beneficial to ensured thinness and lightness of a display panel. Furthermore, an energy utilization rate of the light emitting device within an applicable viewing field angle range may be increased, and brightness enhancement within a viewing angle range may be achieved, which has advantages of thinness and lightness and device integration, and may be applied to brightness enhancement within a viewing angle range in AR thinning transparent display and VR thinning display.

The above description of the embodiment of the near-eye display apparatus is similar to the above description of the embodiment of the display panel, and has similar beneficial effects as the embodiment of the display panel. Technical details undisclosed in the embodiment of the near-eye display apparatus of the present disclosure may be understood by those skilled in the art with reference to the description in the embodiment of the display panel of the present disclosure, which will not be repeated here.

An exemplary embodiment of the present disclosure also provides a virtual/augmented reality device including a near-eye display apparatus in one or more of the above embodiments. For example, the virtual/augmented reality device may be a virtual/augmented reality head-mounted display, or another apparatus or device with a near-eye display function, which may achieve deflection imaging of large-angle light without aberration, and achieve a VR/AR device with characteristics of a large viewing field angle.

Although implementation modes disclosed in the present disclosure are as above, the described contents are only implementation modes used for convenience of understanding the present disclosure and are not intended to limit the present disclosure. Any skilled in the art to which the present disclosure pertains, without departing from the spirit and scope disclosed in the present disclosure, may make any modification and change in a form and details of implementation. However, the scope of patent protection of the present application should still be subject to the scope defined in the appended claims.

1. A display panel, comprising: a central display region and an angle-customized display region surrounding the central display region, wherein the central display region and the angle-customized display region each includes a plurality of sub-pixels, a sub-pixel includes a light emitting device and a metasurface device corresponding to the light emitting device, a metasurface device in the angle-customized display region is configured such that light emitted by a corresponding light emitting device is deflected at a customized angle corresponding to the angle-customized display region.

2. The display panel according to claim 1, wherein, the metasurface device includes a plurality of metasurface units arranged regularly, at least one of the plurality of metasurface units includes a base substrate and a post body disposed on the base substrate, and a refractive index of the base substrate is different from a refractive index of the post body.

3. The display panel according to claim 2, wherein in the central display region, a pixel opening region of the sub-pixel has a first centerline extending along a first direction or a second centerline extending along a second direction, a plurality of metasurface units of the metasurface device are symmetrically disposed with respect to at least one of a geometric center of the sub-pixel, the first centerline, and the second centerline, the second direction intersects with the first direction, and an intersection point of the first centerline and the second centerline is the geometric center of the sub-pixel.

4. The display panel according to claim 2, wherein pixel opening regions of the sub-pixels in the central display region and the angle-customized display region each include a first region, the first region includes a plurality of sub-regions, a diameter of a metasurface unit in a sub-region farther from a geometric center of the sub-pixel in the plurality of sub-regions is smaller, or a diameter of a metasurface unit in a sub-region farther from a geometric center of the first region in the plurality of sub-regions is smaller.

5. The display panel according to claim 4, wherein the pixel opening regions of the sub-pixels in the central display region and the angle-customized display region further each include a second region that at least partially surrounds the first region, and a diameter of a metasurface unit in a region close to the first region in the second region is greater than a diameter of a metasurface unit in a region close to the second region in the first region.

6. (canceled)

7. The display panel according to claim 5, wherein along a direction away from a geometric center of the display panel, the display panel includes N angle-customized display regions, a pixel opening region of a sub-pixel of at least one of the N angle-customized display regions further includes a third region located on a side of the first region away from the second region, a diameter of a metasurface unit in a region close to the first region in the third region is smaller than a diameter of a metasurface unit in a region close to the third region in the first region, the diameter of the metasurface unit in the region close to the first region in the third region is smaller than a diameter of a metasurface unit in a region close to the first region in the second region, and N is a positive integer greater than 1.

8. The display panel according to claim 4, wherein, a distance between a geometric center of a sub-region where a metasurface unit with a largest diameter is located in the plurality of sub-regions in the angle-customized display region and the geometric center of the sub-pixel is a non-zero distance.

9. (canceled)

10. The display panel according to claim 4, wherein a distance between a geometric center of a sub-region where a metasurface unit with a largest diameter is located in the plurality of sub-regions in the central display region and the geometric center of the sub-pixel is a first distance, and a distance between a geometric center of a sub-region where a metasurface unit with a largest diameter in the plurality of sub-regions in the angle-customized display region and the geometric center of the sub-pixel is a second distance, and the first distance is less than the second distance.

11. The display panel according to claim 4, wherein along a direction away from a geometric center of the display panel, the display panel includes N angle-customized display regions, a distance between a geometric center of a sub-region where a metasurface unit with a largest diameter is located in the plurality of sub-regions in an N-th angle-customized display region and the geometric center of the sub-pixel is a third distance, a distance between a geometric center of a sub-region where a metasurface unit with a largest diameter is located in the plurality of sub-regions in an (N−1)-th angle-customized display region and the geometric center of the sub-pixel is a fourth distance, the third distance is greater than the fourth distance, and N is a positive integer greater than 1.

12. The display panel according to claim 4, wherein the first region has a first reference line extending along a first direction or a second reference line extending along a second direction, and in the plurality of sub-regions of the angle-customized display region, metasurface units in at least one of the sub-regions are symmetrically disposed with respect to one of the first reference line and the second reference line, and the second direction intersects with the first direction.

13. The display panel according to claim 2, wherein along a direction away from a geometric center of the display panel, the display panel includes N angle-customized display regions, a customized angle corresponding to an N-th angle-customized display region is greater than a customized angle corresponding to an (N−1)-th angle-customized display region, and N is a positive integer greater than 1.

14. The display panel according to claim 2, wherein the metasurface device in the angle-customized display region satisfies a following phase equation:
$$φ ( x , y ) = - 2 π n ( \sqrt{( {x}^{2} + {y}^{2} ) + {f}^{2}} - f ) / λ + 2 π n ( x cos ϕ + y sin ϕ ) sin θ / λ$$
wherein (x, y) represents coordinates of different position points on the metasurface device, a geometric center of the metasurface device is an origin of the coordinates, φ(x, y) represents a phase at a position point (x, y) on the metasurface device, λ represents a wavelength of incident light, f represents a focal length of a lens when the metasurface device expresses a phase of a beam collection lens, ϕ represents a grating angle when the metasurface device expresses a phase of a deflection grating, and θ is a customized angle corresponding to the angle-customized display region.

15. The display panel according to claim 2, wherein the metasurface device in the angle-customized display region is further configured to enable deflected light to be incident to a lens located on a light exit side of the display panel, and the customized angle corresponding to the angle-customized display region satisfies following equations:
$${θ}_{X} = {tan}^{- 1} \frac{{L}_{1 X} ( 1 - {L}_{2} / {L}_{1} )}{{d}_{1}}$$
$${θ}_{Y} = {tan}^{- 1} \frac{{L}_{1 Y} ( 1 - {L}_{2} / {L}_{1} )}{{d}_{1}}$$
wherein θ_{X} represents a deflection angle of light in an x direction, θ_{Y} represents a deflection angle of light in a y direction, (L_{1X}, L_{1Y}) represents coordinates of a sub-pixel in the angle-customized display region, L₁ represents a length of a display region of the display panel, L₂ represents a diameter of the lens, d₁ represents a distance between the lens and the display panel.

16. The display panel according to claim 2, wherein along a direction away from a geometric center of the display panel, the display panel includes two angle-customized display regions, the metasurface device in the angle-customized display region is further configured to enable deflected light to be incident to a lens located on a light exit side of the display panel;
a customized angle corresponding to an angle-customized display region farther from the center of the display panel satisfies an equation:
$${θ}_{1} = {tan}^{- 1} \frac{( {L}_{1} - {L}_{2} ) / 2}{{d}_{1}} ;$$
a customized angle corresponding to an angle-customized display closer to the center of the display panel satisfies an equation:
$${θ}_{2} = {tan}^{- 1} \frac{( {L}_{1} - {L}_{2} ) / 4}{{d}_{1}} ;$$
wherein L₁ represents a length of a display region of the display panel, L₂ represents a diameter of the lens, d₁ represents a distance between the lens and the display panel.

17. The display panel according to claim 16, wherein a ratio of a length of the central display region to a length of the display region of the display panel is 0.5, a ratio of a in length of the angle-customized display region closer to the geometric center of the display panel to the length of the display region of the display panel is 0.75, and a ratio of the length of the angle-customized display region farther from the geometric center of the display panel to the length of the display region of the display panel is 1.

18. The display panel according to claim 2, wherein the post body is a cylinder, and in at least one metasurface device, a radius of the cylinder is 50 nm to 90 nm; or, the radius of the cylinder is 55 nm to 110 nm; or, the radius of the cylinder is 55 nm to 140 nm.

19. The display panel according to claim 1, wherein in a direction perpendicular to a plane of the display panel, the display panel includes a base substrate, a light emitting structure layer located on a side of the base substrate, and a metasurface structure layer disposed on a side of the light emitting structure layer away from the base substrate, the light emitting structure layer includes a plurality of light emitting devices, and the metasurface structure layer includes a plurality of metasurface devices.

20. The display panel according to claim 19, further comprising: an encapsulation layer and a cover plate layer, wherein the encapsulation layer is disposed on a side of the metasurface structure layer close to the light emitting structure layer, and the cover plate layer is disposed on a side of the metasurface structure layer away from the light emitting structure layer.

21. A near-eye display apparatus, comprising: a display panel according to claim 1 and a light modulation device located on a light exit side of the display panel, wherein a metasurface device in an angle-customized display region of the display panel is configured such that light emitted by a corresponding light emitting device is deflected at a customized angle corresponding to the angle-customized display region and incident to the light modulation device.

22. The near-eye display apparatus according to claim 21, wherein the light modulation device comprises a lens.
